(19) United States
(12) Patent Application Publication
(10) Pub. No.: US 2025/0373227 A1
(43) Pub. Date: Dec. 4, 2025

(54) ACOUSTIC WAVE RESONATOR AND ACOUSTIC WAVE FILTER DEVICE

(71) Applicant: Murata Manufacturing Co., Ltd., Nagaokakyo-shi (JP)

(72) Inventor: Kentaro NAKAMURA, Nagaokakyo-shi (JP)

(21) Appl. No.: 19/169,162

(22) Filed: Apr. 3, 2025

(30) Foreign Application Priority Data
May 31, 2024 (JP) 2024-089334

(51) Int. Cl. H03H 9/13; H03H 9/54

(52) U.S. Cl. CPC H03H 9/132; H03H 9/54

(57) ABSTRACT

An acoustic wave resonator includes a piezoelectric layer and an IDT electrode. Electrode fingers of the IDT electrode are arranged in a first direction along a main surface of the piezoelectric layer. A region where the IDT electrode is provided includes split regions in a matrix in the first direction and a second direction in which the electrode fingers extend. The split region includes some of the electrode fingers and a portion of the electrode fingers in the longitudinal direction. The split regions include one split region and another split region adjacent to each other in the second direction. A duty in the one split region is larger than a duty in the another split region, and an electrode finger pitch in the one split region is smaller than an electrode finger pitch in the another split region.

### CROSS REFERENCE TO RELATED APPLICATIONS

This application claims the benefit of priority to Japanese Patent Application No. 2024-089334 filed on May 31, 2024.The entire contents of this application are hereby incorporated herein by reference.

### BACKGROUND OF THE INVENTION

### 1. Field of the Invention

The present invention relates to acoustic wave resonators and acoustic wave filter devices including acoustic wave resonators.

### 2. Description of the Related Art

Heretofore, an acoustic wave resonator including an IDT electrode has been known. In the acoustic wave resonator, various unwanted waves are generated, other than a main mode used to form a band of a filter. For example, the unwanted waves are generated as shear horizontal (SH) waves, Rayleigh waves, or higher mode waves that are generated outside the band of the filter. The unwanted waves are also generated as longitudinal mode or transverse mode waves even within the band of the filter. In a wireless communication system for communication by bundling a plurality of frequency bands, these unwanted waves need to be suppressed.

International Publication No. 2015/198904 discloses an acoustic wave filter that suppresses Rayleigh wave spurious responses by adjusting a duty of an IDT electrode over the entire length in an acoustic wave propagation direction. International Publication No. 2021/177108 discloses an acoustic wave resonator that reduces the intensity of spurious responses while maintaining the uniformity of resonant frequency.

The acoustic wave resonator described in International Publication No. 2015/198904 can suppress unwanted Rayleigh waves, but has a problem of a decrease in impedance ratio of a main response. The acoustic wave resonator described in International Publication No. 2021/177108 can suppress unwanted Rayleigh waves and can also prevent a decrease in impedance ratio of a main response, but still has a problem of insufficient suppression of unwanted waves.

### SUMMARY OF THE INVENTION

Accordingly, example embodiments of the present invention provide acoustic wave resonators each able to reduce or prevent an increase in unwanted waves.

An acoustic wave resonator according to an example embodiment of the present invention includes a piezoelectric layer, and an IDT electrode on a main surface of the piezoelectric layer, in which the IDT electrode includes a plurality of electrode fingers arranged in a first direction along the main surface of the piezoelectric layer, a region on the main surface of the piezoelectric layer where the IDT electrode includes a plurality of split regions in a matrix in the first direction and a second direction in which the electrode fingers extend, a split region among the plurality of split regions includes some of the plurality of electrode fingers and a portion of the electrode fingers in a longitudinal direction, the plurality of split regions include one split region and another split region adjacent to each other in the second direction, and a duty in the one split region is larger than a duty in the another split region, and an electrode finger pitch in the one split region is smaller than an electrode finger pitch in the another split region.

An acoustic wave filter device according to an example embodiment of the present invention includes an acoustic wave resonator according to an example embodiment of the present invention.

The acoustic wave resonators according to example embodiments of the present invention are each able to reduce or prevent an increase in unwanted waves.

The above and other elements, features, steps,

characteristics and advantages of the present invention will become more apparent from the following detailed description of the example embodiments with reference to the attached drawings.

### BRIEF DESCRIPTION OF THE DRAWINGS

FIG. 1 is a plan view and a sectional view schematically showing an electrode configuration of an acoustic wave resonator according to Example Embodiment 1 of the present invention.

FIG. 2 is a diagram showing first split region groups, second split region groups, and split regions in a region where an IDT electrode is provided.

FIG. 3 is a diagram showing a duty of the IDT electrode.

FIG. 4 is a diagram showing an electrode finger pitch of the IDT electrode.

FIG. 5 is a diagram schematically showing differences in duty between a plurality of split regions.

FIG. 6A is a graph showing changes in duty of split regions in a predetermined second split region group.

FIG. 6B is a graph showing changes in duty of split regions in a plurality of second split region groups.

FIG. 7A is a diagram schematically showing an IDT electrode of the acoustic wave resonator according to Example Embodiment 1.

FIG. 7B is a partially enlarged view of the IDT electrode of the acoustic wave resonator according to Example Embodiment 1.

FIG. 8 is a table showing a specific example of the duties of the plurality of split regions.

FIG. 9 is a table showing a correspondence relationship between the duty and the electrode finger pitch.

FIG. 10 is a graph showing a relationship between the duty and wavelength in a split regions.

FIG. 11 is a diagram schematically showing a cross-section of the acoustic wave resonator according to Example 1 of an example embodiment of the present invention.

FIG. 12 is a diagram showing an IDT electrode of an acoustic wave resonator according to Comparative Example 1.

FIG. 13 is a graph showing impedance characteristics of the acoustic wave resonators according to Example Embodiment 1 and Comparative Example 1.

FIG. 14 is a graph showing return loss of the acoustic wave resonators according to Example Embodiment 1 and Comparative Example 1.

FIG. 15 is a graph showing impedance phase characteristics of the acoustic wave resonators according to Example 1 and Comparative Example 1.

FIG. 16 is a diagram showing an example of an IDT electrode of an acoustic wave resonator according to Example 2 of an example embodiment of the present invention.

FIG. 17A is a graph showing changes in duty of split regions in a predetermined second split region group according to Example 2.

FIG. 17B is a graph showing changes in duty of split regions in a plurality of second split region groups according to Example 2.

FIG. 18 is a diagram showing another example of the IDT electrode of the acoustic wave resonator according to Example 2.

FIG. 19 is a graph showing impedance characteristics of the acoustic wave resonators according to Example 2 and Comparative Example 1.

FIG. 20 is a graph showing return loss of the acoustic wave resonators according to Example 2 and Comparative Example 1.

FIG. 21 is a graph showing impedance phase characteristics of the acoustic wave resonators according to Example 2 and Comparative Example 1.

FIG. 22A is a graph showing changes in duty of split regions in a predetermined second split region group according to Example 3 of an example embodiment of the present invention.

FIG. 22B is a graph showing changes in duty of split regions in a plurality of second split region groups according to Example 3.

FIG. 23A is a graph showing changes in duty of split regions in a predetermined second split region group according to Example 4 of an example embodiment of the present invention.

FIG. 23B is a graph showing changes in duty of split regions in a plurality of second split region groups according to Example 4.

FIG. 24A is a graph showing changes in duty of split regions in a predetermined second split region group according to Example 5 of an example embodiment of the present invention.

FIG. 24B is a graph showing changes in duty of split regions in a plurality of second split region groups according to Example 5.

FIG. 25A is a graph showing changes in duty of split regions in a predetermined second split region group according to Example 6 of an example embodiment of the present invention.

FIG. 25B is a graph showing changes in duty of split regions in a plurality of second split region groups according to Example 6.

FIG. 26A is a graph showing changes in duty of split regions in a predetermined second split region group according to Example 7 of an example embodiment of the present invention.

FIG. 26B is a graph showing changes in duty of split regions in a plurality of second split region groups according to Example 7.

FIG. 27 is a graph showing the impedance phase characteristics s of the acoustic wave resonators according to Examples 1, 2, and 3.

FIG. 28 is a graph showing the impedance phase characteristics of the acoustic wave resonators according to Examples 1, 5, and 6.

FIG. 29 is a table showing maximum values of unwanted responses of Rayleigh waves according to Examples 1, 2, 3, 5, and 6 and Comparative Example 1.

FIG. 30 is a diagram showing an example of an IDT electrode of an acoustic wave resonator according to Example 8 of an example embodiment of the present invention.

FIG. 31 is a diagram showing another example of the IDT electrode of the acoustic wave resonator according to Example 8.

FIG. 32 is a diagram showing another example of a cross-section of the acoustic wave resonator.

FIG. 33 is a diagram showing another example of the cross-section of the acoustic wave resonator.

FIG. 34 is a diagram showing another example of the cross-section of the acoustic wave resonator.

FIG. 35 is a diagram showing another example of the cross-section of the acoustic wave resonator.

FIG. 36 is a diagram showing another example of the cross-section of the acoustic wave resonator.

FIG. 37 is a diagram showing another example of the cross-section of the acoustic wave resonator.

FIG. 38 is a diagram showing another example of the cross-section of the acoustic wave resonator.

FIG. 39 is a diagram showing another example of the cross-section of the acoustic wave resonator.

FIG. 40 is a diagram showing a circuit configuration of an acoustic wave filter device according to Example Embodiment 2 of the present invention.

FIG. 41 is a diagram showing a circuit configuration of a multiplexer and its peripheral circuits according to Example Embodiment 3 of the present invention.

### DETAILED DESCRIPTION OF THE EXAMPLE EMBODIMENTS

Hereinafter, example embodiments of the present invention will be described in detail with reference to the drawings. Example embodiments of the present invention described below are all comprehensive or specific examples. The numerical values, shapes, materials, components, arrangements, and connection configurations of the components, and the like described in the following example embodiments are merely examples and are not intended to limit the present invention. Among the components in the following example embodiments, those not described in the independent claims are described as optional components. In addition, the size or size ratio of the components shown in the drawings is not necessarily strict.

### Example Embodiment 1

### Basic Configuration of Acoustic Wave Resonator

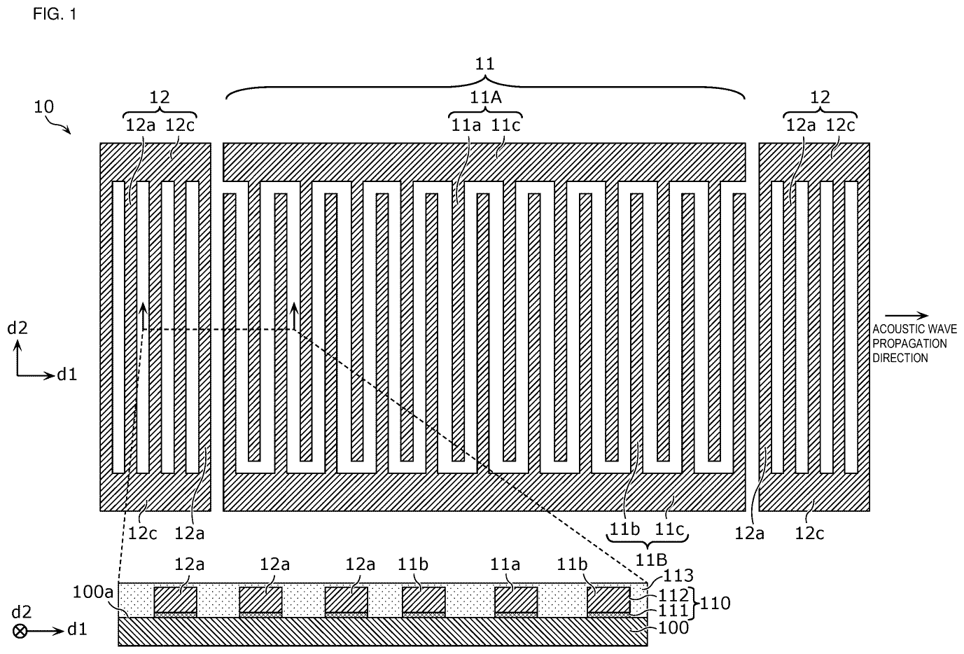

A basic configuration of an acoustic wave resonator according to Example Embodiment 1 of the present invention will be described with reference to FIG. 1.

FIG. 1 is a plan view and a sectional view schematically showing an electrode configuration of an acoustic wave resonator 10 according to Example Embodiment 1.

The acoustic wave resonator 10 shown in FIG. 1 includes a piezoelectric layer 100, an electrode 110, and a protective film 113, and includes an inter digital transducer (IDT) electrode 11 including these components, and a plurality of reflectors 12. The acoustic wave resonator 10 according to the present example embodiment is a surface acoustic wave (SAW) resonator including the IDT electrode 11, the plurality of reflectors 12, and the piezoelectric layer 100.

The acoustic wave resonator 10 shown in FIG. 1 is for illustrating its typical structure, and the number, the length, and other factors of electrode fingers included in the electrode are not limited thereto. The piezoelectric layer 100 may be, for example, a piezoelectric substrate.

The electrode 110 of the IDT electrode 11 and the plurality of reflectors 12 has a multilayer structure including an adhesion layer 111 and a main electrode layer 112, as shown in the sectional view of FIG. 1.

The adhesion layer 111 improves adhesion between the piezoelectric layer 100 and the main electrode layer 112, and is made of Ti, for example.

The main electrode layer 112 is made of Al, for example. The main electrode layer 112 may include,: for example, Cu in addition to Al.

The protective film 113 covers the electrode 110. The protective film 113 is a layer for, for example, protecting the main electrode layer 112 from the external environment, adjusting the frequency-temperature characteristics, and increasing moisture resistance. The protective film 113 is, for example, a film made mainly of silicon dioxide (SiO₂).

The materials of the adhesion layer 111, the main electrode layer 112, and the protective film 113 are not limited to the materials described above. The electrode 110 does not have to have the multilayer structure described above. The electrode 110 may be made of metal or alloy such as Ti, Al, Cu, Pt, Au, Ag, or Pd, for example, or may include a plurality of multilayer bodies made of such metal or alloy. The protective film 113 does not have to be provided.

As shown in the plan view of FIG. 1, the IDT electrode 11 includes a pair of comb-shaped electrodes 11A and 11B facing each other.

Here, a predetermined direction along a main surface 100a of the piezoelectric layer 100 is referred to as a first direction d1, and a direction along the main surface 100a of the piezoelectric layer 100 and intersecting the first direction d1 is referred to as a second direction d2. The first direction d1 is an acoustic wave propagation direction of the acoustic wave resonator 10. In the present example embodiment, the first direction d1 is orthogonal or substantially orthogonal to the second direction d2.

The comb-shaped electrode 11A includes a plurality of electrode fingers 11a extending in the second direction d2, and a busbar electrode the plurality of electrode fingers 11a. The comb-shaped electrode 11B includes a plurality of electrode fingers 11b extending in the second direction d2, and a busbar electrode 11c connecting one ends of the plurality of electrode fingers 11b. The plurality of electrode fingers 11a and 11b are arranged alternately in the first direction d1.

The reflectors 12 are disposed next to the IDT electrode 11 in the first direction d1. The plurality of reflectors 12 are disposed in both outer side portions of the IDT electrode 11. The plurality of reflectors 12 include one reflector 12 located on the negative side of the first direction d1 and the other reflector 12 located on the positive side of the first direction d1 as viewed from the IDT electrode 11. The reflectors 12 each include a plurality of reflection electrode fingers 12a extending in the second direction d2, and a busbar electrode 12c connecting one ends of the plurality of reflection electrode fingers 12a.

### Detailed Configuration of Acoustic Wave Resonator

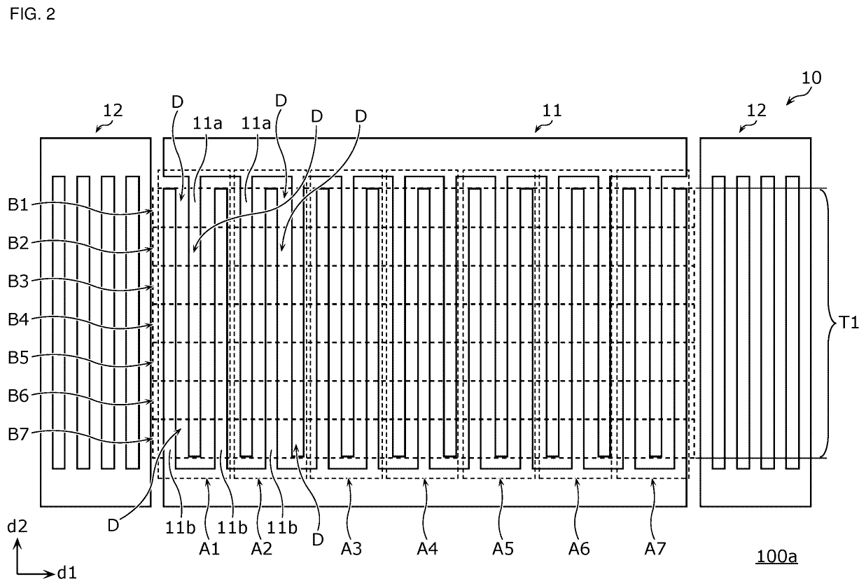

A detailed configuration of the acoustic wave resonator 10 will be described with reference to FIGS. 2 to 6B.

FIG. 2 is a diagram showing first split region groups, second split region groups, and split regions in a region where the IDT electrode 11 is provided.

FIG. 2 shows a plurality of first split region groups A1, A2, A3, A4, A5, A6, and A7, a plurality of second split region groups B1, B2, B3, B4, B5, B6, and B7, and a plurality of split regions D.

The plurality of first split region groups A1 to A7 are regions surrounded by vertically long rectangular dashed lines in FIG. 2. The plurality of first split region groups A1 to A7 are aligned in the first direction d1 in the region where the IDT electrode 11 is provided on the main surface 100a of the piezoelectric layer 100. The plurality of first split region groups A1 to A7 each include a region including one or more electrode fingers 11a (or 11b). In the present example embodiment, the first split region groups A1 to A7 each include a region including three electrode fingers. The first split region groups A1 to A7 are also each configured so as to include the entire longitudinal direction of the electrode fingers extending in the second direction d2. The plurality of first split region groups A1 to A7 have the same or substantially the same length in the first direction d1 and also have the same or substantially the same length in the second direction d2.

In FIG. 2, the plurality of second split region groups B1 to B7 are regions surrounded by horizontally long rectangular dashed lines. The plurality of second split region groups B1 to B7 are aligned in the second direction d2 in the region where the IDT electrode 11 is provided. Specifically, the plurality of second split region groups B1 to B7 are provided in an intersecting region T1 where the plurality of electrode fingers 11a and 11b intersect in the region where the IDT electrode 11 is provided. The intersecting region T1 is a region where the plurality of electrode fingers 11a and 11b overlap when the IDT electrode 11 is viewed from the first direction d1. The plurality of second split region groups B1 to B7 each intersect with the plurality of electrode fingers 11a and 11b. In the present example embodiment, the second split region groups B1 to B7 are each provided across twenty-one electrode fingers 11a and 11b. The plurality of second split region groups B1 to B7 have the same or substantially the same length in the second direction d2 and also have the same or substantially the same length in the first direction d1.

The number of divisions for each of the first split region group and the second split region group is, for example, seven in the above example embodiment, but is not limited thereto. For example, the number of divisions for each of the first split region group and the second split region group may be larger than or equal to two.

The plurality of split regions are regions divided by dashed lines in FIG. 2. The plurality of split regions D are provided in a matrix in the first direction d1 and the second direction d2 in the region where the IDT electrode 11 is provided. The plurality of split regions D are regions defined by the plurality of first split region groups A1 to A7 and the plurality of second split region groups B1 to B7. The plurality of split regions D are arranged in a matrix by being divided by the first split region groups A1 to A7 and the second split region groups B1 to B7. In the present example embodiment, the plurality of split regions D include forty-nine split regions in total, seven in the first direction d1 and seven in the second direction d2.

Each split region D is a region including some of the plurality of electrode fingers 11a and 11b, and a portion of the electrode fingers in the longitudinal direction. In the present example embodiment, each split region D is a region including three electrode fingers and 1/7 of the length of the electrode fingers in the longitudinal direction. The plurality of split regions D have the same or substantially the same length in the first direction d1 and also have the same or substantially the same length in the second direction d2.

In each of the plurality of split regions D, a duty of the electrode is constant and a pitch of the electrode fingers is constant. Here, the duty and electrode finger pitch of the IDT electrode 11 will be described.

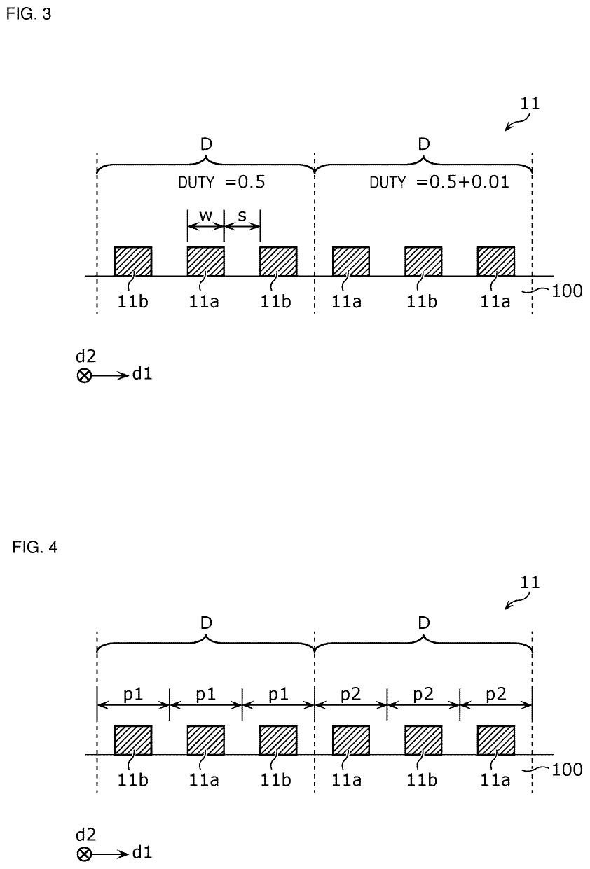

FIG. 3 is a diagram showing the duty of the IDT electrode 11.

The duty is a ratio of the area occupied by the electrode to the unit area. The duty is preset for the electrode fingers in each split region D. For example, the duty is set for each split region D so that it has different values within a predetermined range with, for example, about 0.5 as a base value. The duty is actually derived as follows. For example, when a plurality of electrode fingers 11a and 11b are arranged in the first direction d1, the duty in the split region D is derived by calculation using a width w of the electrode finger as the numerator and the sum of the width w of the electrode finger and a width s of a gap region where no electrode fingers exist as the denominator (duty=w/(w+s)).

FIG. 4 is a diagram showing the electrode finger pitch of the IDT electrode 11.

The electrode finger pitch is an arrangement pitch of the plurality of electrode fingers 11a and 11b arranged in the first direction d1. The electrode finger pitch is preset in accordance with the duty described above. In the example embodiment shown in FIG. 4, p1 is the electrode finger pitch in the split region D of the first split region group A1 and p2 is the electrode finger pitch in the split region D of the first split region group A2. The electrode finger pitch is actually derived as follows. For example, when a plurality of electrode fingers 11a and 11b are arranged in the first direction d1, the electrode finger pitch in the split region D is derived by dividing the distance in the first direction d1 between the electrode fingers at both ends of the split region D by “the number of electrode fingers in the split region D-1”.

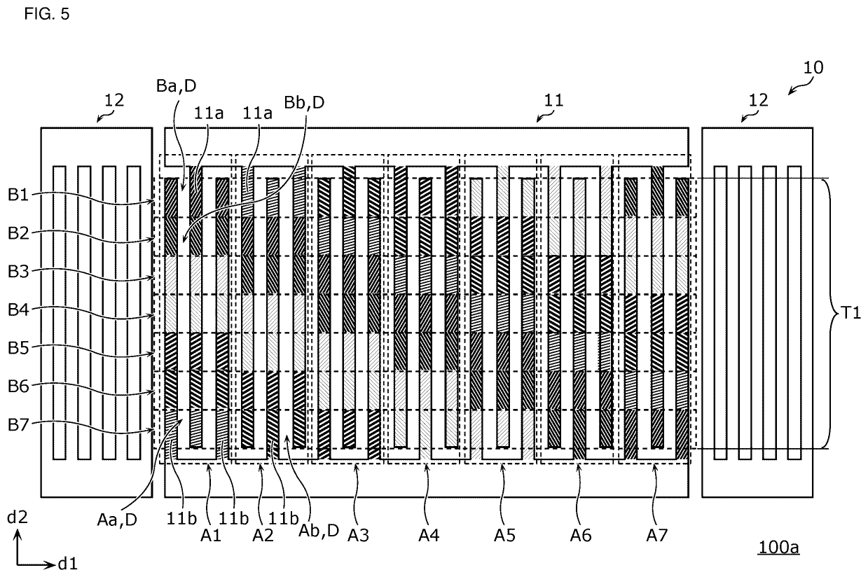

FIG. 5 is a diagram schematically showing differences in duty between a plurality of split regions D.

FIG. 5 shows a plurality of patterns of split regions D with different duties by applying different hatching patterns to the electrode fingers 11a and 11b. In the present example embodiment, FIG. 5 shows seven patterns of split regions D defined by seven patterns of duties. The electrode finger pitch is determined so as to correspond to the seven patterns of duties. As shown in FIG. 5, the plurality of split regions D are configured so that the duty changes continuously in the first direction d1 and the second direction d2.

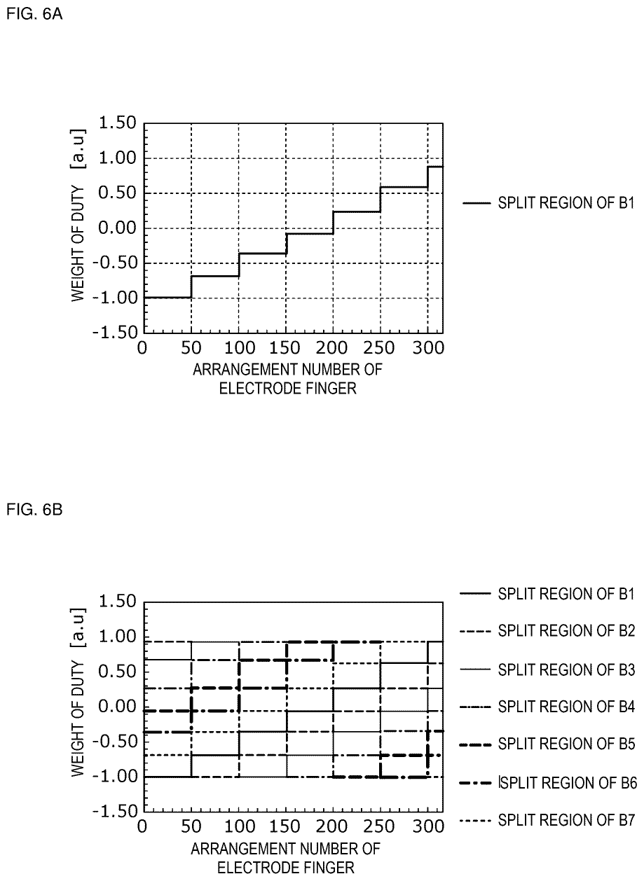

FIG. 6A is a graph showing the change in duty of the split regions D in a predetermined second split region group. FIG. 6B is a graph showing changes in duty of the split regions D in a plurality of second split region groups B1 to B7.

FIGS. 6A and 6B show coordinate systems with the arrangement number of the plurality of electrode fingers 11a and 11b sequentially arranged in the first direction d1 as a first axis and the duty as a second axis. Specifically, the second axis is a function related to the weight of the duty.

FIG. 6A shows how the duty of the split regions D located in the second split region group B1 changes depending on the coordinate position on the first axis. As shown in FIG. 6A, the split regions D are configured so that the duty of the split regions D define a step-like waveform in this coordinate system. FIG. 6B shows how the duties of the split regions D located in the plurality of second split region groups B1 to B7 change depending on the coordinate position on the first axis. As shown in FIG. 6B, the plurality of split regions D are configured so that the duties of the plurality of split regions D define a plurality of waveforms with the same or substantially the same shape but different phases in this coordinate system. The duty changes upward to the right in FIGS. 6A and 6B, but is not limited thereto and may change downward to the right.

As shown in FIG. 5, the plurality of first split region groups A1 to A7 each include one split region Ba and the other split region Bb adjacent to each other in the second direction d2. In the present example embodiment, the duty in one split region Ba is larger than the duty in the other split region Bb, and the electrode finger pitch in one split region Ba is smaller than the electrode finger pitch in the other split region Bb.

For example, when one split region Ba is a split region D of the second split region group B1 (hereinafter referred to as B1) and the other split region Bb is a split region D of the second split region group B2 (hereinafter referred to as B2), the duty in the split region D of B1 is larger than the duty in the split region of B2, and the electrode finger pitch in the split region D of B1 is smaller than the electrode finger pitch in the split region D of B2. These relationships may be reversed. That is, when one split region Ba is the split region D of B2 and the other split region Bb is the split region D of B1, the duty in the split region D of B2 may be larger than the duty in the split region of B1, and the electrode finger pitch in the split region D of B2 may be smaller than the electrode finger pitch in the split region D of B1. The same applies to such relationships for the other second split region groups B2 to B7.

Furthermore, as shown in FIG. 5, the plurality of second split region groups B1 to B7 each include one split region Aa and the other split region Ab adjacent to each other in the first direction d1. In the present example embodiment, the duty in one split region Aa is larger than the duty in the other split region Ab, and the electrode finger pitch in one split region Aa is smaller than the electrode finger pitch in the other split region Ab.

For example, when one split region Aa is a split region D of the first split region group A1 (hereinafter referred to as A1) and the other split region Ab is a split region D of the first split region group A2 (hereinafter referred to as A2), the duty in the split region D of A1 is larger than the duty in the split region of A2, and the electrode finger pitch in the split region D of A1 is smaller than the electrode finger pitch in the split region D of A2. These relationships may be reversed. That is, when one split region Aa is the split region D of A2 and the other split region Ab is the split region D of Al, the duty in the split region D of A2 may be larger than the duty in the split region of A1, and the electrode finger pitch in the split region D of A2 may be smaller than the electrode finger pitch in the split region D of A1. The same applies to such relationships for the other first split region groups A2 to A7.

In the present example embodiment, in one split region Aa and the other split region Ab adjacent to each other in the first direction d1, a resonant frequency determined based on the duty and electrode finger pitch in one split region Aa matches a resonant frequency determined based on the duty and electrode finger pitch in the other split region Ab. Similarly, in one split region Ba and the other split region Bb adjacent to each other in the second direction d2, a resonant frequency determined based on the duty and electrode finger pitch in one split region Ba matches a resonant frequency determined based on the duty and electrode finger pitch in the other split region Bb.

Specifically, the acoustic wave resonator 10 has a configuration in which the split regions D adjacent to each other in the first direction d1 have different duties and electrode finger pitches, the split regions D adjacent to each other in the second direction d2 have different duties and electrode finger pitches, and the resonant frequencies match in these adjacent split regions D.

Such differences in duty between the adjacent split regions D make it possible to appropriately distribute the frequencies of unwanted waves such as longitudinal mode waves and Rayleigh waves. This makes it possible to reduce or prevent an increase in the unwanted waves. Furthermore, with the resonant frequencies matching in a main mode, a decrease in impedance ratio can be prevented and therefore characteristic degradation in the main mode can be reduced or prevented.

### Acoustic Wave Resonator of Example 1

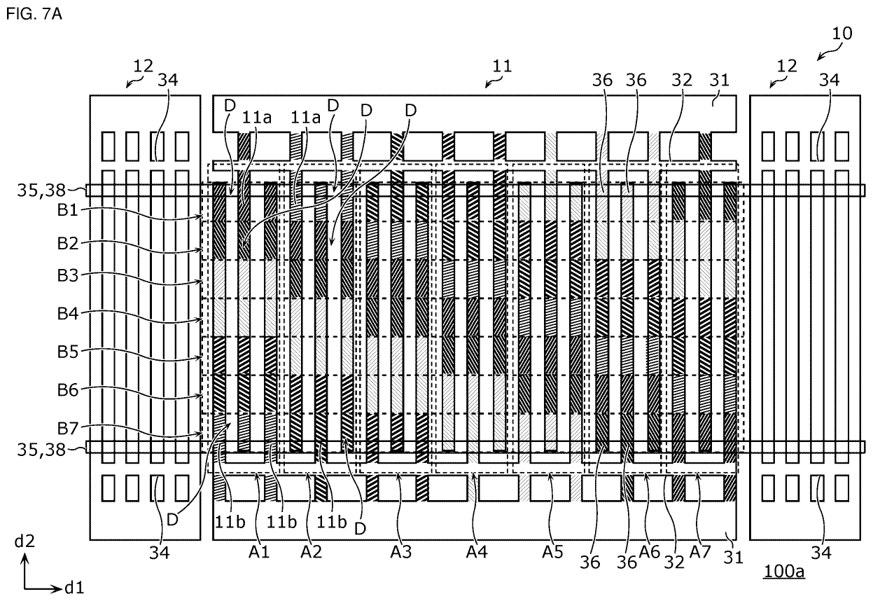

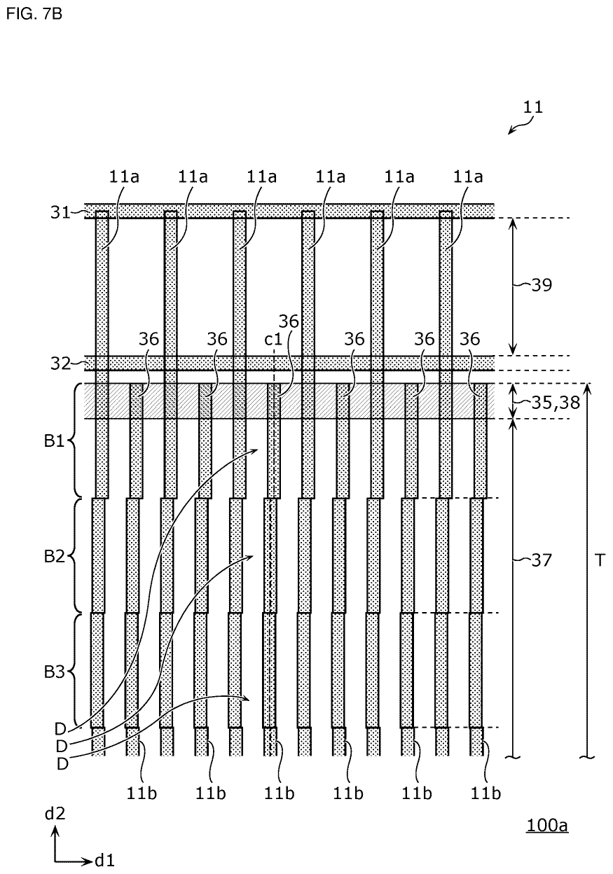

An acoustic wave resonator 10 of Example 1 as one of the examples of Example Embodiment 1 will be described with reference to FIGS. 7A to 15.

FIG. 7A is a diagram schematically showing the IDT electrode 11 of the acoustic wave resonator 10 of Example 1. FIG. 7B is a partially enlarged view of the IDT electrode 11 of the acoustic wave resonator 10 according to Example 1.

As shown in FIG. 7A, the acoustic wave resonator 10 includes an IDT electrode 11 and a plurality of reflectors 12. FIG. 7A is a schematic diagram, and the actual number of pairs of electrode fingers is different from that shown. For example, the number of pairs of electrode fingers 11a and 11b of the IDT electrode 11 is 158, and the number of pairs of reflection electrode fingers 12a of the reflector 12 is 10.

As shown in FIG. 7A, the IDT electrode 11 includes a pair of comb-shaped electrodes 11A and 11B. The pair of comb-shaped electrodes 11A and 11B each include a plurality of electrode fingers 11a and 11b, and a first busbar electrode 31 connecting one ends of the plurality of electrode fingers 11a and 11b.

Since the duty and the electrode finger pitch pattern are different between the plurality of split regions D as described above, the electrode fingers 11a and 11b are configured to have a stepped shape as shown in FIG. 7B. The electrode fingers are shifted in the first direction d1 so that the position of a center line c1 of the width of the electrode finger is different at the boundary between the split regions D adjacent to each other in the second direction d2. The shift amount in the first direction d1 of two electrode fingers in contact with each other at the boundary between the split regions D is smaller than the width dimension of the electrode finger.

As shown in FIG. 7A, the pair of comb-shaped electrodes 11A and 11B each include a second busbar electrode 32 that is thinner than the first busbar electrode 31. As shown in FIG. 7B, a high acoustic velocity portion 39 is provided between the first busbar electrode 31 and the second busbar electrode 32. That is, the high acoustic velocity portion 39 is provided between both end portions 36 of the electrode fingers 11a and 11b and the first busbar electrode 31.

The second busbar electrode 32 is provided parallel or substantially parallel to the first busbar electrode 31 between the first busbar electrode 31 and the plurality of split regions D. The plurality of split regions D are regions that coincide with the intersecting region T1 where the plurality of electrode fingers 11a and 11b intersect. The intersecting width of the electrode fingers 11a and 11b of the IDT electrode 11 is, for example, about 11.62 λ. Here, λ is a reference wavelength. In the present example, for example, λ=about 1.98030 μm. A gap is provided between the tip of the electrode finger 11a (or 11b) and the second busbar electrode 32. The gap between the tip of the electrode finger 11a or 11b and the second busbar electrode 32 is, for example, about 0.135 λ.

In the present example, a second busbar electrode 34 that is thinner than the busbar electrode 12c is also provided in the reflector 12. The second busbar electrode 34 of the reflector 12 is provided at the same or substantially the same position as the second busbar electrode 32 in the second direction d2.

As shown in FIGS. 7A and 7B, the IDT electrode 11 includes piston mode formation regions 35 located at both end portions 36 of the electrode fingers 11a and 11b. The piston mode formation regions 35 are provided at both end portions 36 different from central portions 37 (see FIG. 7B) of the electrode fingers 11a and 11b. The piston mode formation regions 35 are included in the split regions D located at both ends in the second direction d2, among the plurality of split regions D.

As shown in FIGS. 7A and 7B, a piston mode is applied to the IDT electrode 11 by providing load films 38 in both end portions 36 of the electrode fingers 11a and 11b. The load film 38 defines and functions as a weight for the electrode fingers 11a and 11b, and includes an electrode film or insulating film, for example. The load film 38 has a line shape parallel or substantially parallel to the second busbar electrode 32, and is provided at the end portion of the intersecting region T1 located closer to the center than the second busbar electrode 32. The piston mode formation region 35 is not limited to the load film 38, and may include a wide electrode portion that is wider than the width of the electrode fingers 11a and 11b. This wide electrode portion may be rectangular or substantially rectangular, T-shaped, plus (+)-shaped, or convex. In the present example, a piston mode formation region 35 is also provided in the reflector 12. The piston mode formation region 35 of the reflector 12 is provided at the same or substantially the same position as the piston mode formation region 35 of the IDT electrode 11 in the second direction d2.

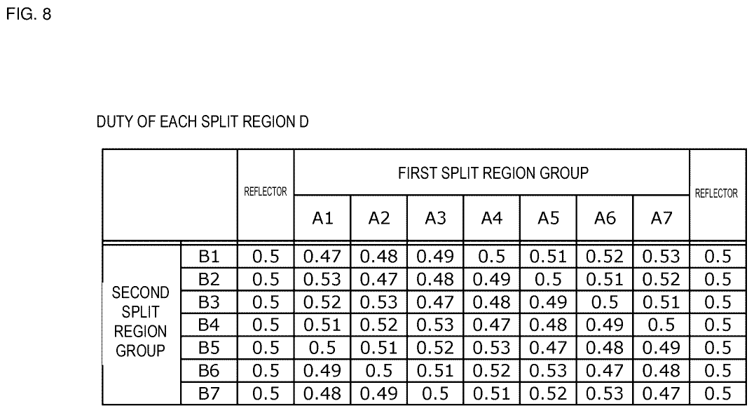

FIG. 8 is a table showing a specific example of the duties of the plurality of split regions D.

FIG. 8 shows the duties of the plurality of split regions D defined by the plurality of first split region groups A1 to A7 and the plurality of second split region groups B1 to B7. FIG. 8 also shows the duty of the reflector 12. In the present example, the duty is changed so that the amount of change falls within the range of about +0.03, with the duty=about 0.5 as a reference. As shown in the table of FIG. 8, the plurality of split regions D are provided so that a predetermined duty changes by moving linearly and continuously in the first direction d1 and the second direction d2. In the present example, the predetermined duty is set to move diagonally downward to the right.

For example, as for the duties of the plurality of split regions D shown in FIG. 8, a standard model with the same duty (for example, about 0.5) and the same or substantially the same electrode finger pitch (for example, about 1.9803 μm) is created, and different duties are assigned to each split region D of a predetermined second split region group (for example, B1) of the standard model, and different duties are assigned to each split region D of the plurality of first split region groups A1 to A7 based on the duty of the split region D. The different duties are assigned under predetermined rules. The electrode finger pitch is set to be different for each split region D in accordance with the duty.

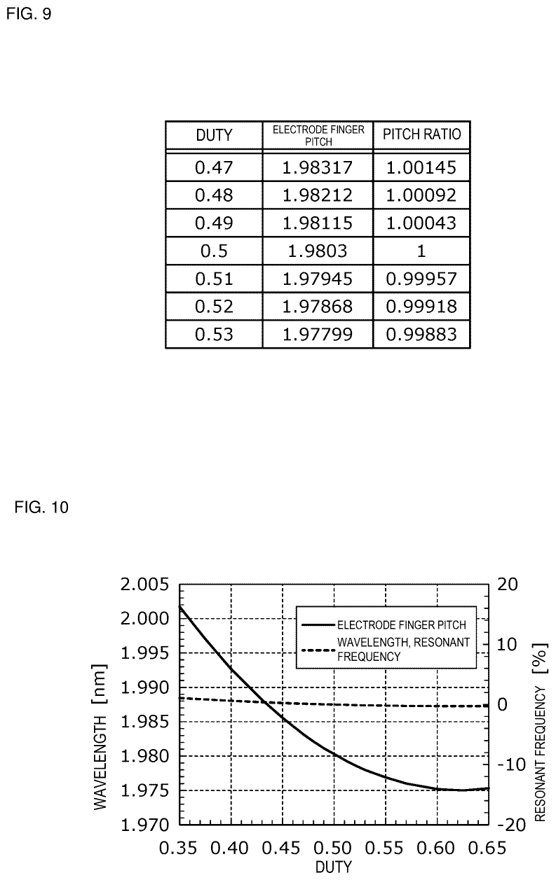

FIG. 9 is a table showing a correspondence relationship between the duty and the electrode finger pitch.

FIG. 9 shows the electrode finger pitch and pitch ratio relative to the duty in FIG. 8. The pitch ratio is expressed as a ratio based on the electrode finger pitch (=about 1.9803) when the duty is about 0.5. As shown in FIG. 9, the electrode finger pitch is set in accordance with the change in duty. The duty and the electrode finger pitch in the present example embodiment are set so that the resonant frequencies of the split regions D match or substantially match.

FIG. 10 is a graph showing a relationship between the duty and wavelength in the split region D.

In FIG. 10, the horizontal axis represents the duty and the vertical axis represents the wavelength and the resonant frequency. The wavelength is about twice the electrode finger pitch. Since the inverse of the wavelength is proportional to the frequency, changes in frequency can be seen by observing changes in wavelength. As shown in FIG. 10, the electrode finger pitch is changed according to the change in duty, thus making the resonant frequency match or substantially match between the split regions D.

Here, in this specification, the expression “one frequency and the other frequency match or substantially match” means that the absolute value of the difference between the two frequencies is, for example, less than or equal to about 108. It is preferable that the absolute value of the frequency difference is, for example, less than or equal to about 2%. It is more preferable that the absolute value of the frequency difference is, for example, less than or equal to about 1%.

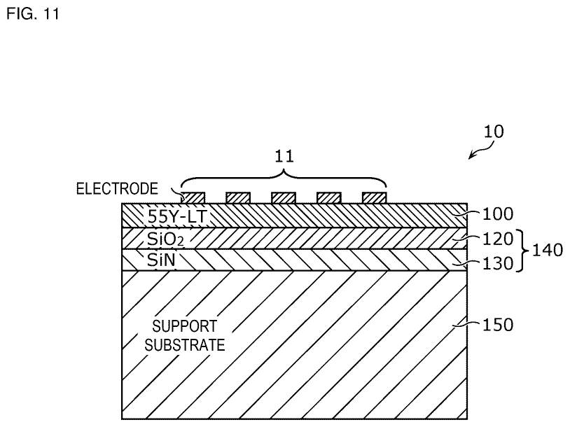

FIG. 11 is a diagram schematically showing a cross-section of the acoustic wave resonator 10 according to Example 1.

As shown in FIG. 11, the acoustic wave resonator 10 includes the IDT electrode 11, a piezoelectric layer 100, a low acoustic velocity layer 120, a high acoustic velocity layer 130, and a support substrate 150. The low acoustic velocity layer 120 and the high acoustic velocity layer 130 define an intermediate layer 140 located between the piezoelectric layer 100 and the support substrate 150.

For example, the IDT electrode 11 is made of a material including A1. The IDT electrode 11 has a thickness of about 100 nm (=about 0.05 λ), for example. The piezoelectric layer 100 is made of LT (lithium tantalate single crystal or ceramics), for example. For example, the piezoelectric layer 100 is “rotated Y-cut 55Y-X LT”. The low acoustic velocity layer 120 is made of SiO₂, for example. The high acoustic velocity layer 130 is made of SiN, for example. The support substrate 150 is made of Si(111)ψ73°, for example. Specifically, the acoustic wave resonator 10 of Example 1 is configured to have a multilayer structure expressed by “LT/SiO₂/SiN/Si(111)ψ73°”. The thicknesses of LT/SiO₂/SiN/Si are about 0.2 λ/about 0.15 λ/about 0.15 λ, respectively.

The advantageous effects of the acoustic wave resonator 10 according to Example 1 having the above configuration will be described while comparing Example 1 and Comparative Example 1.

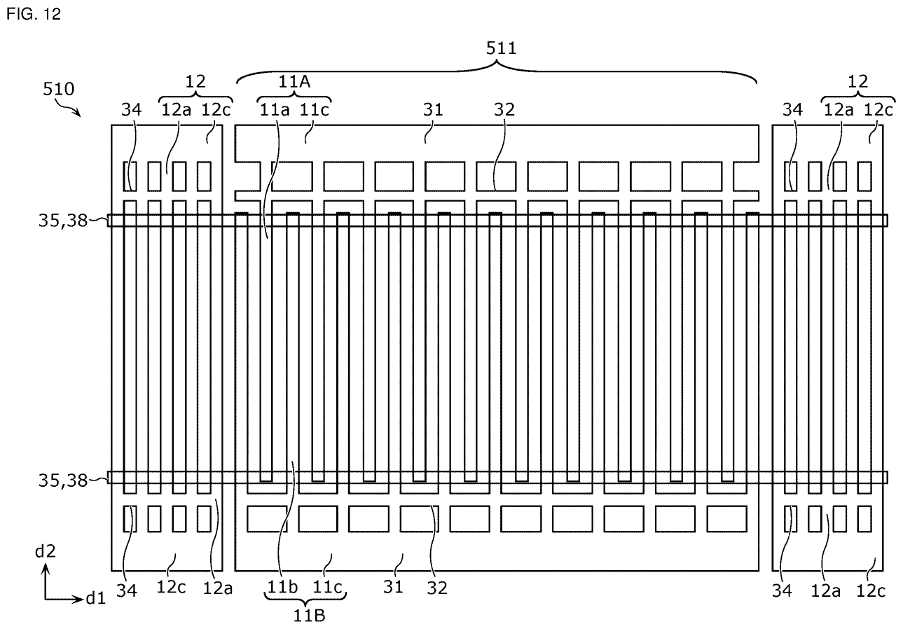

FIG. 12 is a diagram showing an IDT electrode 511 of an acoustic wave resonator 510 according to Comparative Example 1.

The acoustic wave resonator 510 of Comparative Example 1 includes the IDT electrode 511 and a plurality of reflectors 12. The numbers of pairs of electrodes of the IDT electrode 511 and the reflectors 12 are the same as in Example 1. The intersecting width of electrode fingers 11a and 11b of the IDT electrode 511 is the same or substantially the same as in Example 1.

The IDT electrode 511 includes a pair of comb-shaped electrodes 11A and 11B. The pair of comb-shaped electrodes 11A and 11B each include a plurality of electrode fingers 11a and 11b, a first busbar electrode 31 connecting one ends of the plurality of electrode fingers 11a and 11b, and a second busbar electrode 32 that is thinner than the first busbar electrode 31. The gap between the tips of the electrode fingers 11a and 11b and the second busbar electrode 32 is the same or substantially the same as in Example 1. The IDT electrode 511 and the reflector 12 also have a piston mode formation region 35, as in Example 1.

In the acoustic wave resonator 510 of Comparative Example 1, a plurality of split regions D all have the same duty of about 0.5, for example. In the acoustic wave resonator 510 of Comparative Example 1, the plurality of split regions D also all have the same or substantially the same electrode finger pitch.

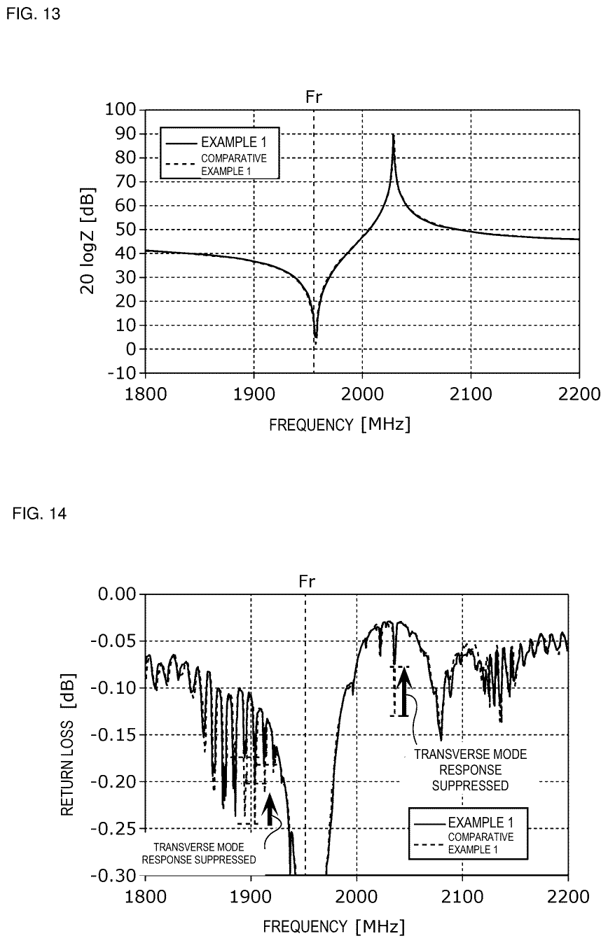

FIG. 13 is a graph showing impedance characteristics of the acoustic wave resonators according to Example 1 and Comparative Example 1.

FIG. 13 shows the impedance characteristics in a main mode of the acoustic wave resonators. As shown in FIG. 13, the acoustic wave resonator 10 of Example 1 has the same or substantially the same impedance ratio as that of the acoustic wave resonator 510 of Comparative Example 1. In other words, the acoustic wave resonator 10 of Example 1 has its characteristics maintained in the main mode.

FIG. 14 is a graph showing return loss of the acoustic wave resonators according to Example 1 and Comparative Example 1.

FIG. 14 shows the return loss in the main mode of the acoustic wave resonators. As shown in FIG. 14, the acoustic wave resonator 10 of Example 1 has reduced or prevented responses in the longitudinal mode and transverse mode, compared to the acoustic wave resonator 510 of Comparative Example 1.

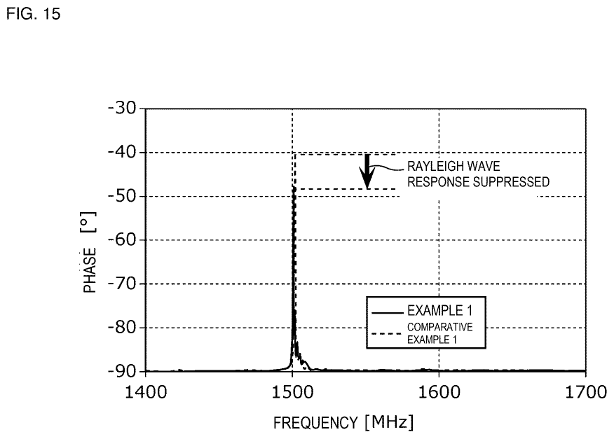

FIG. 15 is a graph showing impedance phase

characteristics of the acoustic wave resonators according to Example 1 and Comparative Example 1.

FIG. 15 shows a response of Rayleigh waves generated outside the band. As shown in FIG. 15, the response of Rayleigh waves is reduced or prevented in the acoustic wave resonator 10 of Example 1, compared to the acoustic wave resonator 510 of Comparative Example 1.

The acoustic wave resonator 10 of Example 1 can thus reduce or prevent unwanted waves compared to Comparative Example 1.

### Acoustic Wave Resonator of Example 2

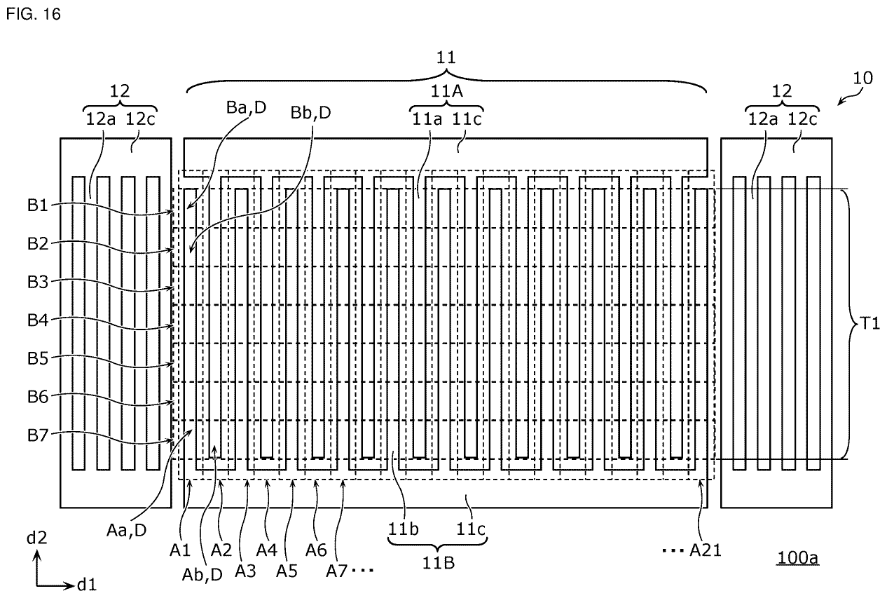

An acoustic wave resonator 10 of Example 2 as one of the examples of Example Embodiment 1 will be described with reference to FIGS. 16 to 21. In Example 2, description will be provided of an example where a first split region group includes a region including only one electrode finger.

FIG. 16 is a diagram showing an example of an IDT electrode 11 of the acoustic wave resonator 10 according to Example 2.

The acoustic wave resonator 10 includes the IDT electrode 11 and a plurality of reflectors 12. The IDT electrode 11 includes a pair of comb-shaped electrodes 11A and 11B facing each other.

The comb-shaped electrode 11A includes a plurality of electrode fingers 11a extending in the second direction d2, and a busbar electrode 11c connecting one ends of the plurality of electrode fingers 11a. The comb-shaped electrode 11B includes a plurality of electrode fingers 11b extending in the second direction d2, and a busbar electrode 11c connecting one ends of the plurality of electrode fingers 11b. The plurality of electrode fingers 11a and 11b are arranged alternately in the first direction d1.

The reflectors 12 are disposed next to the IDT electrode 11 in the first direction d1. The plurality of reflectors 12 are disposed in both outer side portions of the IDT electrode 11. The reflectors 12 each include a plurality of reflection electrode fingers 12a extending in the second direction d2, and a busbar electrode 12c connecting one ends of the plurality of reflection electrode fingers 12a.

In a region where the IDT electrode 11 is provided, a plurality of first split region groups A1 to A21, a plurality of second split region groups B1 to B7, and a plurality of split regions D are provided.

The plurality of first split region groups A1 to A21 are aligned in the first direction d1 in the region where the IDT electrode 11 is provided on a main surface 100a of the piezoelectric layer 100. The first split region groups A1 to A21 each include a region including one electrode finger 11a (or 11b). The first split region groups A1 to A21 are each configured so as to include the entire or substantially the entire longitudinal direction of the electrode finger extending in the second direction d2. The plurality of first split region groups A1 to A21 have the same or substantially the same length in the first direction d1 and also have the same or substantially the same length in the second direction d2.

The plurality of second split region groups B1 to B7 are aligned in the second direction d2 in the region where the IDT electrode 11 is provided. Specifically, the plurality of second split region groups B1 to B7 are provided in the intersecting region T1 where the plurality of electrode fingers 11a and 11b intersect, in the region where the IDT electrode 11 is provided. The plurality of second split region groups B1 to B7 each intersect with the electrode fingers 11a and 11b. In the present example, the second split region groups B1 to B7 are each provided across twenty-one electrode fingers 11a and 11b. The plurality of second split region groups B1 to B7 have the same or substantially the same length in the second direction d2 and also have the same or substantially the same length in the first direction d1.

The plurality of split regions D are provided in a matrix in the first direction d1 and the second direction d2 in the region where the IDT electrode 11 is provided. The plurality of split regions D are regions defined by the plurality of first split region groups A1 to A21 and the plurality of second split region groups B1 to B7. The plurality of split regions D are arranged in a matrix by being divided by the first split region groups A1 to A21 and the second split region groups B1 to B7. In the present example, the plurality of split regions D include 147 split regions in total, twenty-one in the first direction d1 and seven in the second direction d2.

Each split region D is a region including some of the plurality of electrode fingers 11a and 11b, and a portion of the electrode fingers in the longitudinal direction. In the present example, each split region D is a region including one electrode finger and about 1/7 of the length of the electrode finger in the longitudinal direction. The plurality of split regions D have the same or substantially the same length in the first direction d1 and also have the same or substantially the same length in the second direction d2. In each of the plurality of split regions D, a duty of the electrode is constant. The pitch of the electrode fingers in the split region D is constant.

FIG. 17A is a graph showing the change in duty of the split regions D in a predetermined second split region group according to Example 2. FIG. 17B is a graph showing changes in duty of the split regions D in the plurality of second split region groups B1 to B7 according to Example 2.

FIGS. 17A and 17B show coordinate systems with the arrangement number of the plurality of electrode fingers 11a and 11b sequentially arranged in the first direction d1 as a first axis and the duty as a second axis. Specifically, the second axis is a function related to the weight of the duty.

FIG. 17A shows how the duty of the split regions D located in the second split region group B1 changes depending on the coordinate position on the first axis. As shown in FIG. 17A, the split regions D are provided so that the duty of the split regions D generates a triangular waveform in this coordinate system. FIG. 17B shows how the duties of the split regions D located in the plurality of second split region groups B1 to B7 change depending on the coordinate position on the first axis. As shown in FIG. 17B, the plurality of split regions D are configured so that the duties of the plurality of split regions D generate a plurality of waveforms with the same or substantially the same shape but different phases in this coordinate system.

As shown in FIG. 16, the plurality of first split region groups A1 to A21 each include one split region Ba and the other split region Bb adjacent to each other in the second direction d2. In the present example, the duty in one split region Ba is larger than the duty in the other split region Bb, and the electrode finger pitch in one split region Ba is smaller than the electrode finger pitch in the other split region Bb.

Furthermore, as shown in FIG. 16, the plurality of second split region groups B1 to B7 each include one split region Aa and the other split region Ab adjacent to each other in the first direction d1. In the present example, the duty in one split region Aa is larger than the duty in the other split region Ab, and the electrode finger pitch in one split region Aa is smaller than the electrode finger pitch in the other split region Ab.

In the present example, in one split region Aa and the other split region Ab adjacent to each other in the first direction d1, a resonant frequency determined based on the duty and electrode finger pitch in one split region Aa matches or substantially matches a resonant frequency determined based on the duty and electrode finger pitch in the other split region Ab. Similarly, in one split region Ba and the other split region Bb adjacent to each other in the second direction d2, a resonant frequency determined based on the duty and electrode finger pitch in one split region Ba matches or substantially matches a resonant frequency determined based on the duty and electrode finger pitch in the other split region Bb.

Specifically, the acoustic wave resonator 10 of Example 2 has a configuration in which the split regions D adjacent to each other in the first direction d1 have different duties and electrode finger pitches, the split regions D adjacent to each other in the second direction d2 have different duties and electrode finger pitches, and the resonant frequencies match in these adjacent split regions.

Such differences in duty between the adjacent split regions D make it possible to appropriately distribute the frequencies of unwanted waves such as longitudinal mode waves and Rayleigh waves. This makes it possible to reduce or prevent an increase in the unwanted waves. Furthermore, with the resonant frequencies matching in the main mode, a decrease in impedance ratio can be prevented and therefore characteristic degradation in the main mode can be reduced or prevented.

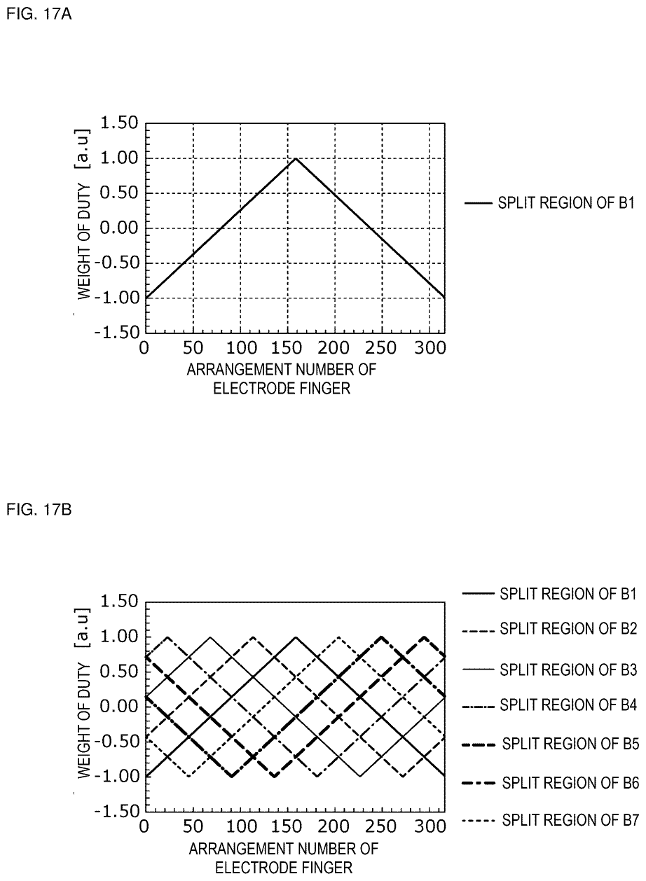

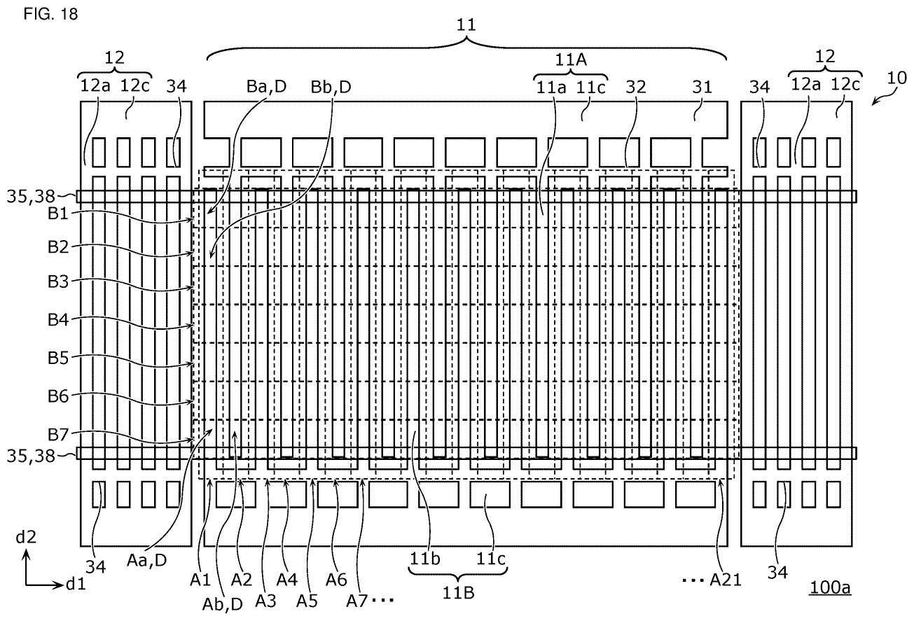

FIG. 18 is a diagram showing another example of the IDT electrode 11 of the acoustic wave resonator 10 according to Example 2.

The acoustic wave resonator 10 of Example 2 includes the IDT electrode 11 and a plurality of reflectors 12. FIG. 18 is a schematic diagram, and the actual number of pairs of electrode fingers is different from that shown. For example, the actual number of pairs of electrode fingers 11a and 11b of the IDT electrode 11 is 158, and the actual number of pairs of reflection electrode fingers 12a of the reflector 12 is 10.

As shown in FIG. 18, the IDT electrode 11 includes a pair of comb-shaped electrodes 11A and 11B. The pair of comb-shaped electrodes 11A and 11B each include a plurality of electrode fingers 11a and 11b, and a first busbar electrode 31 connecting one ends of the plurality of electrode fingers 11a and 11b. The plurality of split regions D have different duties and electrode finger pitch patterns.

As shown in FIG. 18, the pair of comb-shaped electrodes 11A and 11B each include a second busbar electrode 32 that is thinner than the first busbar electrode 31. In the present example, a second busbar electrode 34 that is thinner than the busbar electrode 12c is also provided in the reflector 12. The IDT electrode 11 also includes piston mode formation regions 35 located at both end portions 36 of the electrode fingers 11a and 11b.

The advantageous effects of the acoustic wave resonator 10 according to Example 2 having the above configuration will be described by comparing Example 2 with Comparative Example 1. The acoustic wave resonator used to confirm the advantageous effects is the acoustic wave resonator 10 shown in FIG. 18. The acoustic wave resonator 510 of Comparative Example 1 has the configuration described above.

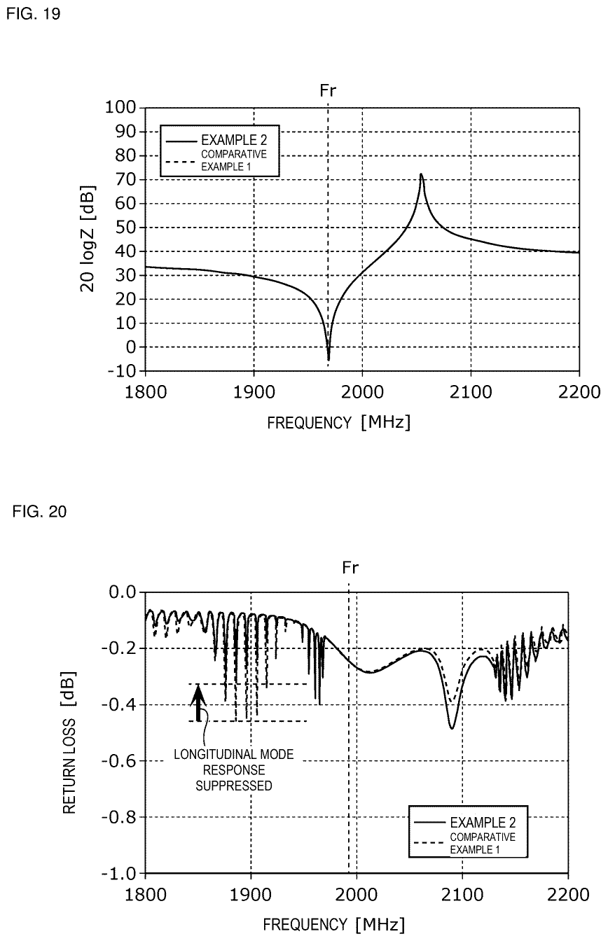

FIG. 19 is a graph showing impedance characteristics of the acoustic wave resonators according to Example 2 and Comparative Example 1.

FIG. 19 shows the impedance characteristics in a main mode of the acoustic wave resonators. As shown in FIG. 19, the acoustic wave resonator 10 of Example 2 has the same or substantially the same impedance ratio as that of the acoustic wave resonator 510 of Comparative Example 1. In other words, the acoustic wave resonator 10 of Example 2 has its characteristics maintained in the main mode.

FIG. 20 is a graph showing return loss of the acoustic wave resonators according to Example 2 and Comparative Example 1.

FIG. 20 shows the return loss in the main mode of the acoustic wave resonators. As shown in FIG. 20, the acoustic wave resonator 10 of Example 2 has reduced responses in the longitudinal mode, compared to the acoustic wave resonator 510 of Comparative Example 1.

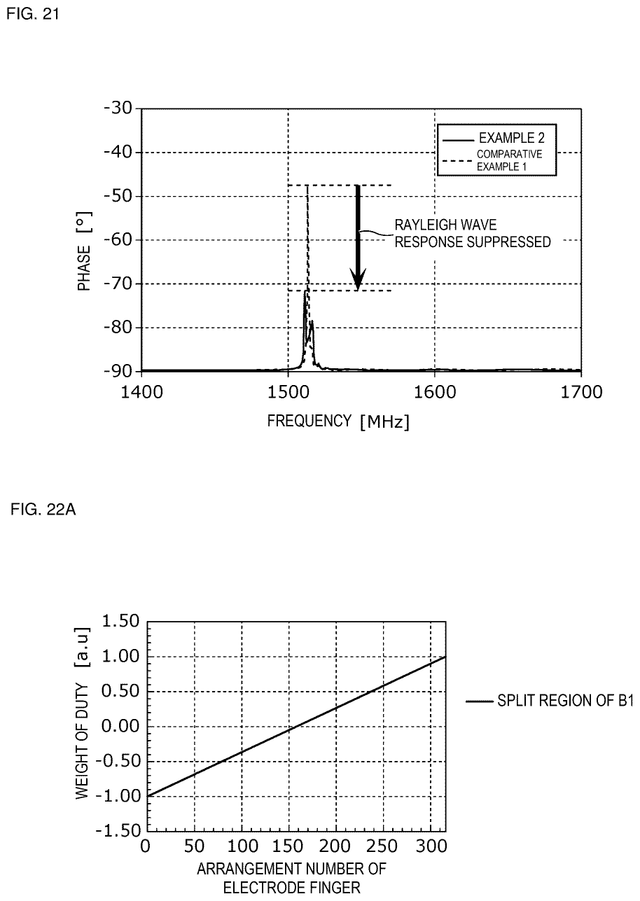

FIG. 21 is a graph showing impedance phase characteristics of the acoustic wave resonators according to Example 2 and Comparative Example 1.

FIG. 21 shows a response of Rayleigh waves generated outside the band. As shown in FIG. 21, the response of Rayleigh waves is reduced or prevented in the acoustic wave resonator 10 of Example 2, compared to the acoustic wave resonator 510 of Comparative Example 1.

The acoustic wave resonator 10 of Example 2 can thus reduce or prevent unwanted waves compared to Comparative Example 1.

### Acoustic Wave Resonators of Examples 3, 4, 5, 6, and 7

Acoustic wave resonators 10 of Examples 3 to 7 as examples of Example Embodiment 1 will be described. In Examples 3 to 7, description will be provided as an example where changes in duty of the split region D are different with the basic configuration of Example 2.

First, Example 3 will be described.

FIG. 22A is a graph showing the change in duty of the split regions D in a predetermined second split region group according to Example 3. FIG. 22B is a graph showing changes in duty of the split regions D in a plurality of second split region groups B1 to B7 according to Example 3.

FIGS. 22A and 22B show coordinate systems with the arrangement number of a plurality of electrode fingers 11a and 11b sequentially arranged in the first direction d1 as a first axis and the duty as a second axis. Specifically, the second axis is a function related to the weight of the duty. As for the coordinate systems, the same applies to the following drawings.

FIG. 22A shows how the duty of the split regions D located in the second split region group B1 changes depending on the coordinate position on the first axis. As shown in FIG. 22A, the split region D is configured so that the duty of the split region D generates a sawtooth waveform in this coordinate system. FIG. 22B shows how the duties of the split regions D located in the plurality of second split region groups B1 to B7 change depending on the coordinate position on the first axis. As shown in FIG. 22B, the plurality of split regions D are configured so that the duties of the plurality of split regions D generate a plurality of waveforms with the same or substantially the same shape but different phases in this coordinate system.

Next, Example 4 will be described.

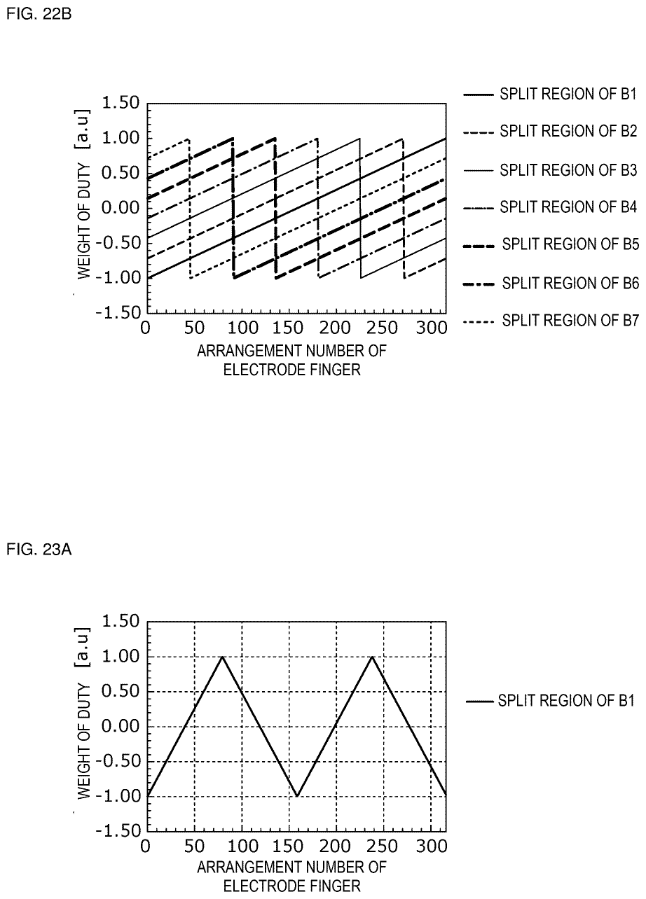

FIG. 23A is a graph showing the change in duty of the split regions D in a predetermined second split region group according to Example 4. FIG. 23B is a graph showing changes in duty of the split regions D in a plurality of second split region groups B1 to B7 according to Example 4.

FIG. 23A shows how the duty of the split regions D located in the second split region group B1 changes depending on the coordinate position on the first axis. As shown in FIG. 23A, the split regions D are configured so that the duty of the split regions D generates a plurality of triangular waveforms in this coordinate system. FIG. 23B shows how the duties of the split regions D located in the plurality of second split region groups B1 to B7 change depending on the coordinate position on the first axis. As shown in FIG. 23B, the plurality of split regions D are configured so that the duties of the plurality of split regions D generate a plurality of waveforms with the same shape but different phases in this coordinate system.

Next, Example 5 will be described.

FIG. 24A is a graph showing the change in duty of the split regions D in a predetermined second split region group according to Example 5. FIG. 24B is a graph showing changes in duty of the split regions D in a plurality of second split region groups B1 to B7 according to Example 5.

FIG. 24A shows how the duty of the split regions D located in the second split region group B1 changes depending on the coordinate position on the first axis. As shown in FIG. 24A, the split regions D are configured so that the duty of the split regions D changes in a curved manner, specifically, changes in a curved waveform of one period, in this coordinate system. The curved waveform is, for example, a sine waveform. FIG. 24B shows how the duties of the split regions D located in the plurality of second split region groups B1 to B7 change depending on the coordinate position on the first axis. As shown in FIG. 24B, the plurality of split regions D are configured so that the duties of the plurality of split regions D generate a plurality of waveforms with the same shape but different phases in this coordinate system.

Next, Example 6 will be described.

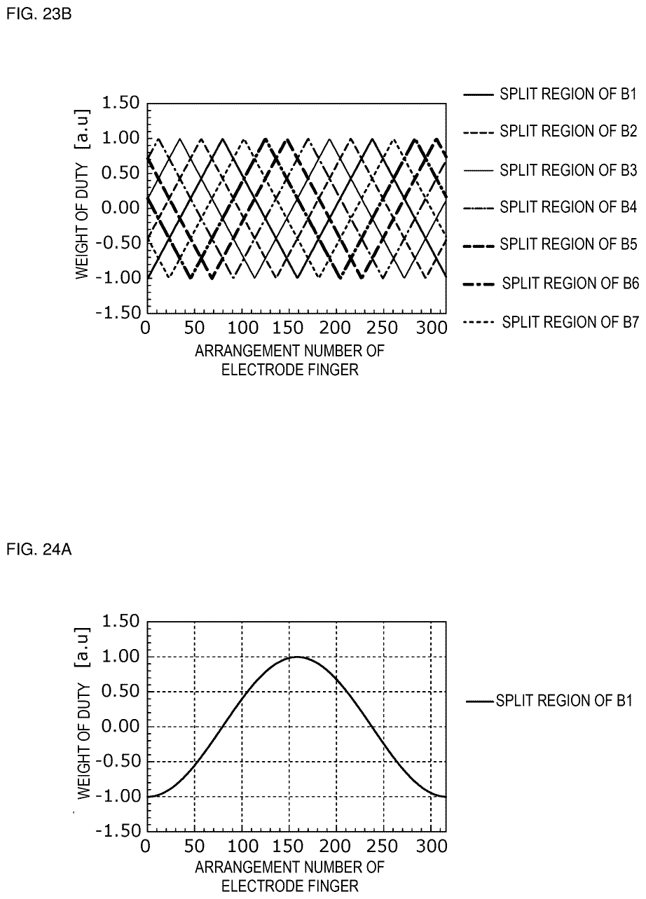

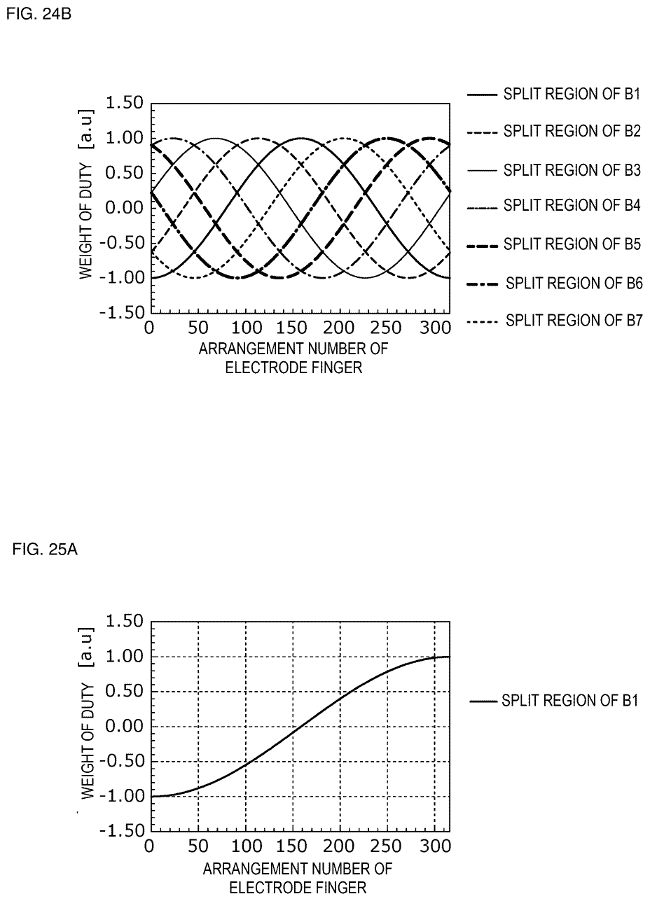

FIG. 25A is a graph showing the change in duty of the split regions D in a predetermined second split region group according to Example 6. FIG. 25B is a graph showing changes in duty of the split regions D in a plurality of second split region groups B1 to B7 according to Example 6.

FIG. 25A shows how the duty of the split regions D located in the second split region group B1 changes depending on the coordinate position on the first axis. As shown in FIG. 25A, the split regions D are configured so that the duty of the split regions D changes in a curved waveform of less than one period or less than or equal to about ½ period in this coordinate system. FIG. 25B shows how the duties of the split regions D located in the plurality of second split region groups B1 to B7 change depending on the coordinate position on the first axis. As shown in FIG. 25B, the plurality of split regions D are configured so that the duties of the plurality of split regions D generate a plurality of waveforms with the same or substantially the same shape but different phases in this coordinate system.

Next, Example 7 will be described.

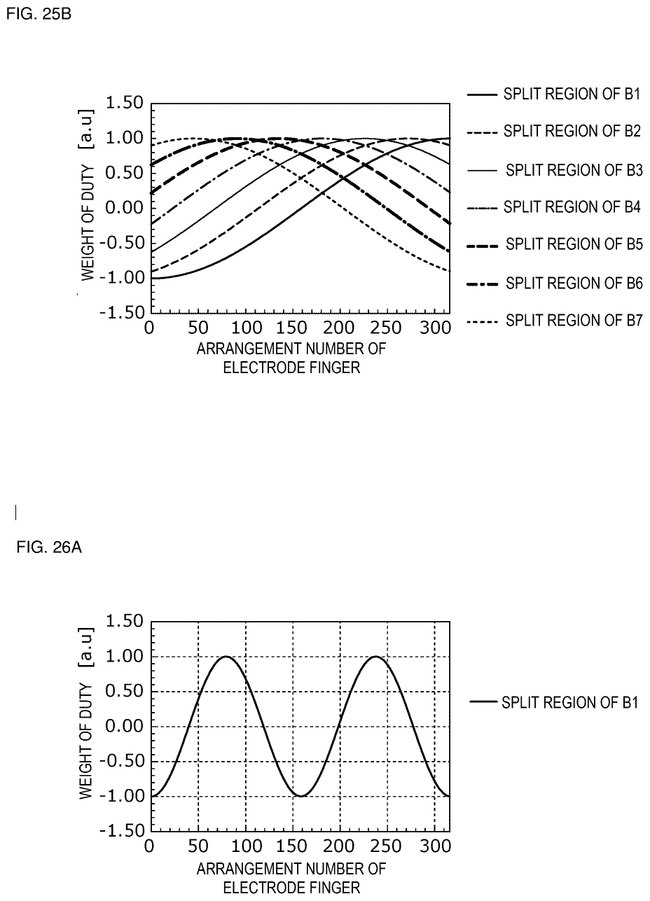

FIG. 26A is a graph showing the change in duty of the split regions D in a predetermined second split region group according to Example 7. FIG. 26B is a graph showing changes in duty of the split regions D in a plurality of second split region groups B1 to B7 according to Example 7.

FIG. 26A shows how the duty of the split regions D located in the second split region group B1 changes depending on the coordinate position on the first axis. As shown in FIG. 26A, the split regions D are configured so that the duty of the split regions D changes in a curved waveform with a plurality of periods, that is, more than one period, in this coordinate system. FIG. 26B shows how the duties of the split regions D located in the plurality of second split region groups B1 to B7 change depending on the coordinate position on the first axis. As shown in FIG. 26B, the plurality of split regions D are configured so that the duties of the plurality of split regions D generate a plurality of waveforms with the same or substantially shape but different phases in this coordinate system.

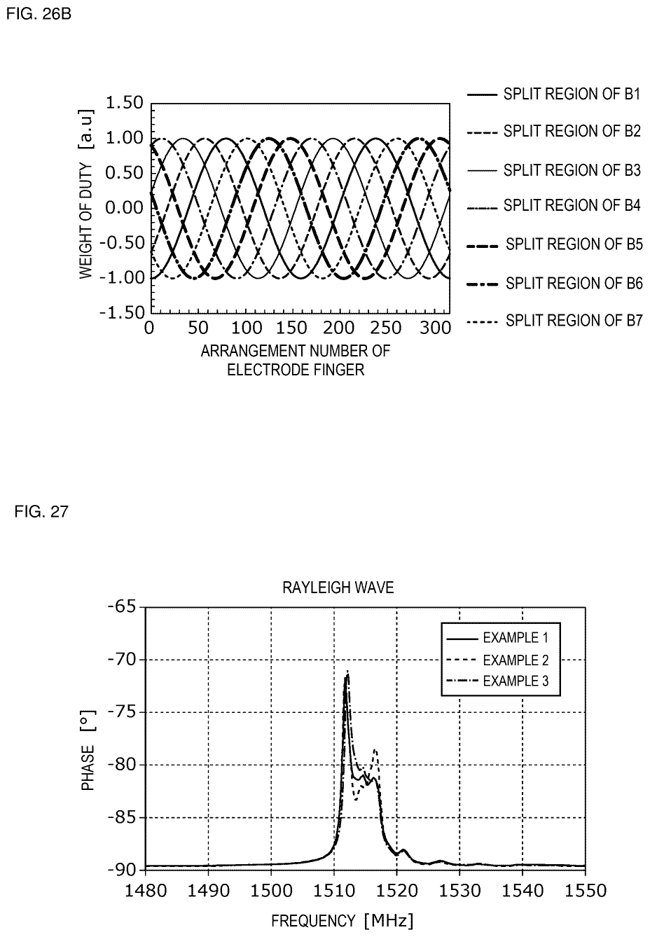

FIG. 27 is a graph showing impedance phase characteristics of the acoustic wave resonators 10 according to Examples 1, 2, and 3.

FIG. 27 shows a response of Rayleigh waves generated outside the band. As shown in FIG. 27, the response of Rayleigh waves is reduced or prevented in the acoustic wave resonators 10 of Examples 1, 2, and 3.

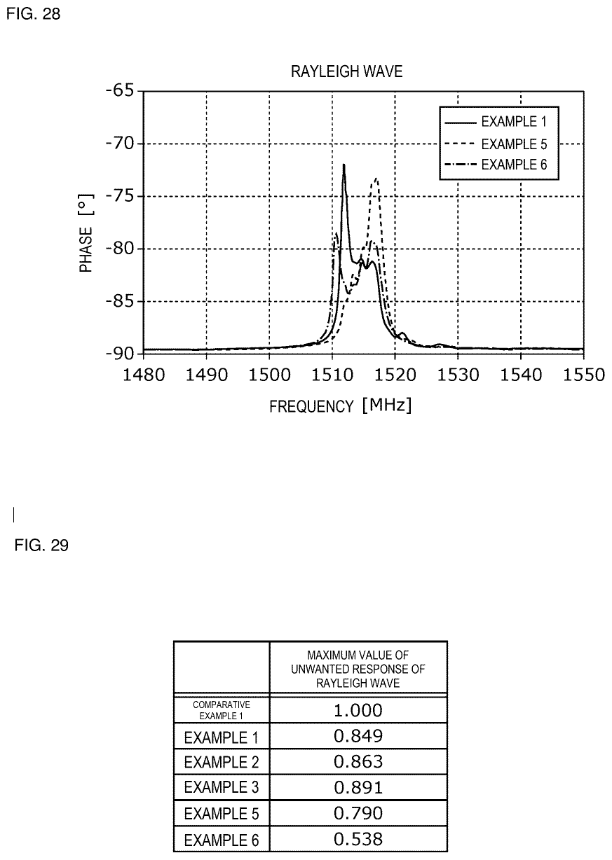

FIG. 28 is a graph showing impedance phase characteristics of the acoustic wave resonators 10 according to Examples 1, 5, and 6.

FIG. 28 shows a response of Rayleigh waves generated outside the band. As shown in FIG. 28, in the acoustic wave resonators 10 of Examples 5 and 6, Rayleigh waves are dispersed differently from Example 1, and the response of Rayleigh waves is reduced or prevented compared to Example 1.

FIG. 29 is a table showing maximum values of unwanted responses of Rayleigh waves according to Examples 1, 2, 3, 5, and 6 and Comparative Example 1.

FIG. 29 shows the maximum values of the unwanted responses of the Rayleigh waves with Comparative Example 1 as a reference. As shown in FIG. 29, the maximum value of the unwanted response of the Rayleigh waves is smaller in Examples 1, 2, 3, 5, and 6 than in Comparative Example 1. Furthermore, the maximum value of the unwanted response of the Rayleigh waves is smaller in Examples 5 and 6 than in Examples 1, 2, and 3.

### Acoustic Wave Resonator of Example 8

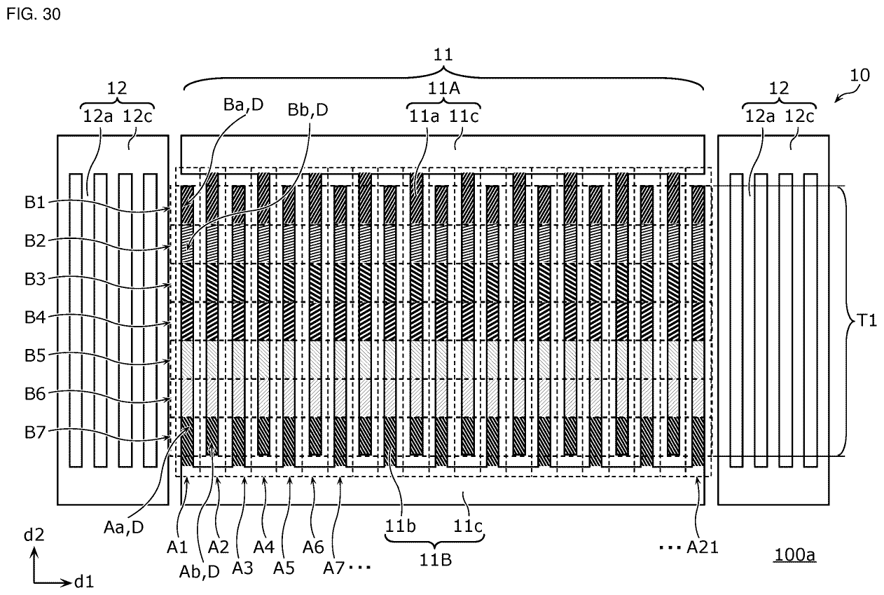

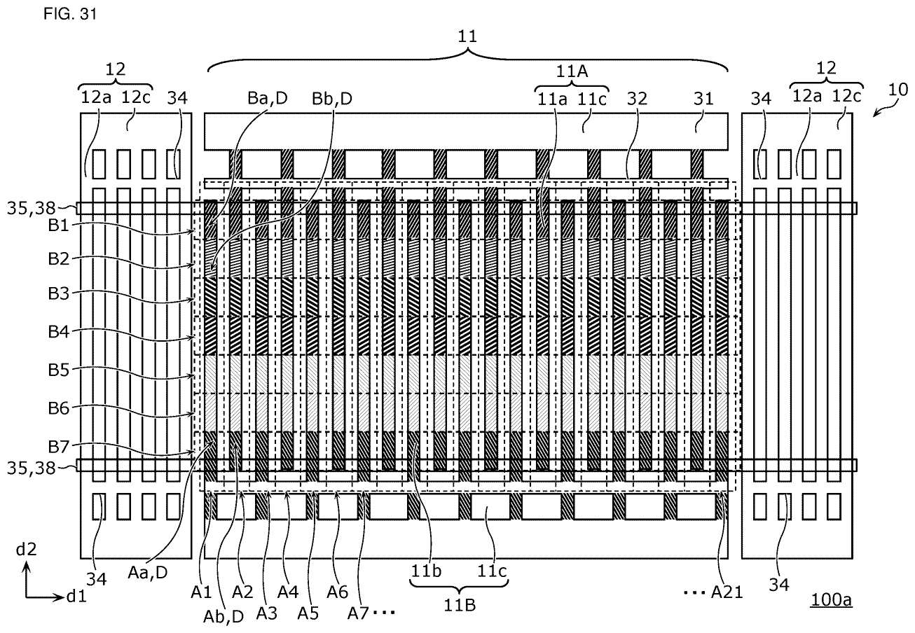

An acoustic wave resonator 10 of Example 8 as one of the examples of Example Embodiment 1 will be described with reference to FIGS. 30 and 31. In Example 8, description will be provided of an example where the duty and electrode finger pitch of the split region D are provided randomly.

FIG. 30 is a diagram showing an example of an IDT electrode 11 of the acoustic wave resonator 10 according to Example 8.

The acoustic wave resonator 10 includes the IDT electrode 11 and a plurality of reflectors 12. The IDT electrode 11 includes a pair of comb-shaped electrodes 11A and 11B facing each other.

The comb-shaped electrode 11A includes a plurality of electrode fingers 11a extending in the second direction d2, and a busbar electrode 11c connecting one ends of the plurality of electrode fingers 11a. The comb-shaped electrode 11B includes a plurality of electrode fingers 11b extending in the second direction d2, and a busbar electrode 11c connecting one ends of the plurality of electrode fingers 11b. The plurality of electrode fingers 11a and 11b are arranged alternately in the first direction d1.

The reflectors 12 are disposed next to the IDT electrode 11 in the first direction d1. The plurality of reflectors 12 are disposed in both outer side portions of the IDT electrode 11. The reflectors 12 each include a plurality of reflection electrode fingers 12a extending in the second direction d2, and a busbar electrode 12c connecting one ends of the plurality of reflection electrode fingers 12a.

In a region where the IDT electrode 11 is provided, a plurality of first split region groups A1 to A21, a plurality of second split region groups B1 to B7, and a plurality of split regions D are provided.

The plurality of first split region groups A1 to A21 are aligned in the first direction d1 in the region where the IDT electrode 11 is provided on a main surface 100a of the piezoelectric layer 100. The plurality of first split region groups A1 to A21 each include a region including one or more electrode fingers 11a (or 11b). In the present example, the first split region groups A1 to A21 each include a region including only one electrode finger. The first split region groups A1 to A21 are each provided so as to include the entire longitudinal direction of the electrode finger extending in the second direction d2.

The plurality of second split region groups B1 to B7 are aligned in the second direction d2 in the region where the IDT electrode 11 is provided. Specifically, the plurality of second split region groups B1 to B7 are provided in the intersecting region T1 where the plurality of electrode fingers 11a and 11b intersect, in the region where the IDT electrode 11 is provided. The plurality of second split region groups B1 to B7 each intersect with the electrode fingers 11a and 11b. In the present example, the second split region groups B1 to B7 are each provided across twenty-one electrode fingers 11a and 11b.

The plurality of split regions D are provided in a matrix in the first direction d1 and the second direction d2 in the region where the IDT electrode 11 is provided. The plurality of split regions D are regions defined by the plurality of first split region groups A1 to A21 and the plurality of second split region groups B1 to B7. The plurality of split regions D are provided in a matrix by being divided by the first split region groups A1 to A21 and the second split region groups B1 to B7. In the present example, the plurality of split regions D include 147 split regions in total, twenty-one in the first direction d1 and seven in the second direction d2.

Each split region D is a region including some of the plurality of electrode fingers 11a and 11b, and a portion of the electrode fingers in the longitudinal direction. In the present example, each split region D is a region including one electrode finger and about 1/7 of the length of the electrode finger in the longitudinal direction. The plurality of split regions D have the same or substantially the same length in the first direction d1 and also have the same or substantially the same length in the second direction d2. In each of the plurality of split regions D, a duty of the electrode is constant. The pitch of the electrode fingers in the split region D is constant.

The plurality of first split region groups A1 to A21 each include one split region Ba and the other split region Bb adjacent to each other in the second direction d2. In the present example, the duty in one split region Ba is larger than the duty in the other split region Bb, and the electrode finger pitch in one split region Ba is smaller than the electrode finger pitch in the other split region Bb.

The plurality of second split region groups B1 to B7 each include one split region Aa and the other split region Ab adjacent to each other in the first direction d1. In the present example, the duty in one split region Aa is larger than the duty in the other split region Ab, and the electrode finger pitch in one split region Aa is smaller than the electrode finger pitch in the other split region Ab. In FIG. 30, the same hatching is used for the electrode fingers of each split region D in each second split region group, but the split regions D actually have different duties.

In the present example, in one split region Aa and the other split region Ab adjacent to each other in the first direction d1, a resonant frequency determined based on the duty and electrode finger pitch in one split region Aa matches or substantially matches a resonant frequency determined based on the duty and electrode finger pitch in the other split region Ab. Similarly, in one split region Ba and the other split region Bb adjacent to each other in the second direction d2, a resonant frequency determined based on the duty and electrode finger pitch in one split region Ba matches or substantially matches a resonant frequency determined based on the duty and electrode finger pitch in the other split region Bb.

Furthermore, in the present example, the duties of the plurality of split regions D are configured to change randomly. For example, it is preferable that all adjacent split regions D have different duties. However, the present invention is not limited thereto, and some of the adjacent split regions D may have the same or substantially the same duty. In other words, at least some of the adjacent split regions D of the plurality of split regions D may have different duties. The electrode finger pitch is set so that the resonant frequencies of the split regions D match or substantially match.

Such randomly changing duties of the split regions D make it possible to distribute the frequencies of unwanted waves such as longitudinal mode waves and Rayleigh waves. This makes it possible to prevent an increase in the unwanted waves. Furthermore, with the resonant frequencies matching or substantially matching in a main mode, a decrease in impedance ratio can be prevented and therefore characteristic degradation in the main mode can be reduced or prevented.

FIG. 31 is a diagram showing another example of the IDT electrode of the acoustic wave resonator according to Example 8.

The acoustic wave resonator 10 of Example 8 includes an IDT electrode 11 and a plurality of reflectors 12. FIG. 31 is a schematic diagram, and the actual number of pairs of electrode fingers is different. For example, the actual number of pairs of electrode fingers 11a and 11b of the IDT electrode 11 is 158, and the actual number of pairs of reflection electrode fingers 12a of the reflector 12 is 10.

As shown in FIG. 31, the IDT electrode 11 includes a pair of comb-shaped electrodes 11A and 11B. The pair of comb-shaped electrodes 11A and 11B each include a plurality of electrode fingers 11a and 11b, and a first busbar electrode 31 connecting one ends of the plurality of electrode fingers 11a and 11b. The plurality of split regions D have different duties and electrode finger pitch patterns.

As shown in FIG. 31, the pair of comb-shaped electrodes 11A and 11B each include a second busbar electrode 32 that is thinner than the first busbar electrode 31. In the present example, a second busbar electrode 34 that is thinner than the busbar electrode 12c is also provided in the reflector 12. The IDT electrode 11 also includes piston mode formation regions 35 located at both end portions 36 of the electrode fingers 11a and 11b. The acoustic wave resonator 10 of Example 8 can reduce or prevent unwanted waves.

### Other Examples

Other examples of the acoustic wave resonator 10 will be described.

In the above examples, the amount of change in duty is, for example, about 0.5±0.03. However, the present invention is not limited thereto, and the amount of change in duty may be, for example, about 0.5±0.05 or about 0.5±0.07. Unwanted responses can be dispersed by increasing the amount of change. However, increasing the amount of change too much leads to the characteristic degradation in the main mode. The amount of change in duty may therefore be, for example, about 0.5±0.2 or less.

The duty of the reflector 12 is constant in the above example, but the present invention is not limited thereto. For example, in the acoustic wave resonator 10, a plurality of split regions including the IDT electrode 11 and the reflector 12 may be provided, and the respective split regions may have different duties. The shape of the split region is not limited to a rectangular or substantially rectangular shape, and may be a square, polygonal, or curved shape.

When the acoustic wave resonator includes a plurality of split resonators, split regions may be provided for each of the plurality of split resonators, and the respective split regions may have different duties.

The generation frequency of unwanted waves may be dispersed by adjusting the electrode thickness and the protective film thickness in addition to the duty. The parameters to be adjusted are not limited to the duty, but may be, for example, at least one of the electrode finger pitch, electrode film thickness, protective film thickness, and film thickness of the laminated substrate including the piezoelectric layer, or a combination thereof.

The piezoelectric layer 100 is not limited to LT, but may be LN (lithium niobate), for example. The orientation and cut-angles of the piezoelectric layer 100 are not limited to those described above.

The IDT electrode 11 of the acoustic wave resonator 10 may be applied to an IDT including longitudinal coupling.

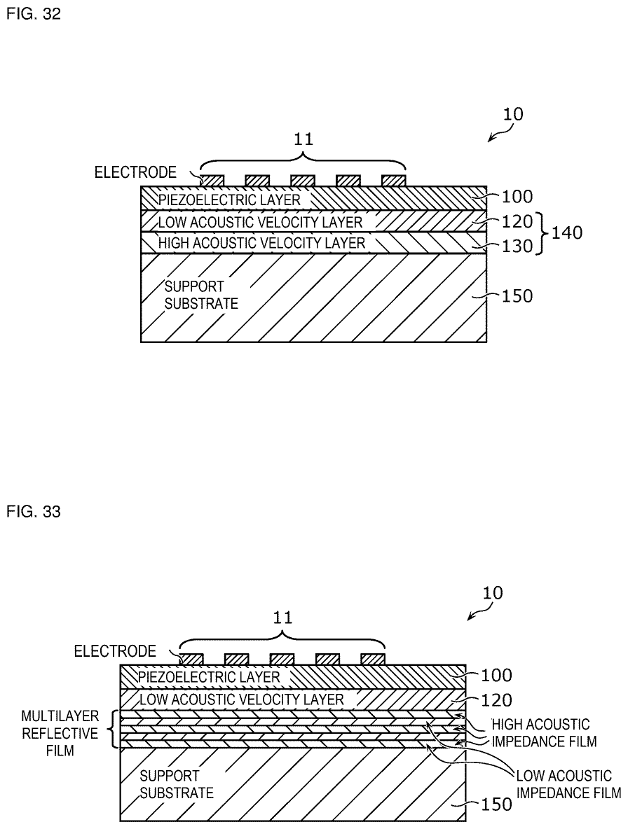

FIGS. 32 to 39 are diagrams showing other examples of the cross-section of the acoustic wave resonator 10.

A substrate for the acoustic wave resonator may be a single piezoelectric single crystal substrate, or a composite substrate in which a piezoelectric layer and a support substrate are laminated together.

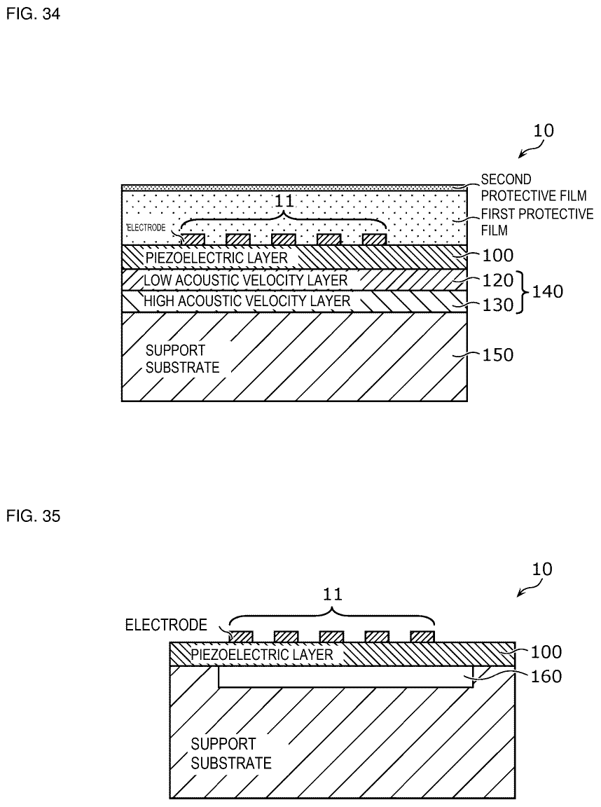

The composite substrate may have a multilayer structure including a piezoelectric layer, a low acoustic velocity layer, a high acoustic velocity layer, and a support substrate (see FIG. 32). The composite substrate may have a configuration including a piezoelectric layer and a support substrate. Alternatively, the composite substrate may have a configuration in which a multilayer reflective layer including a low acoustic impedance film and a high acoustic impedance film is provided between the piezoelectric layer and the support substrate (see FIG. 33). Furthermore, in the above configuration, an IDT electrode 11 may be covered with a first protective film (temperature compensation film) and a second protective film (moisture-resistant film) (see FIG. 34). A dielectric film may be provided between the IDT electrode 11 and the piezoelectric layer.

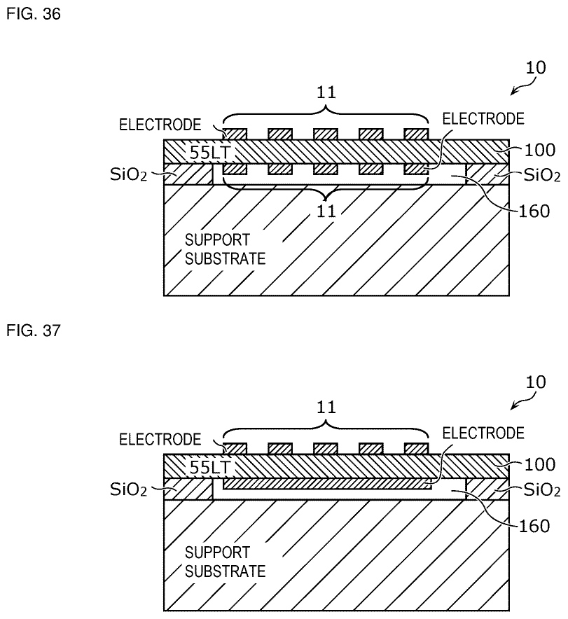

A hollow region 160 may be provided under the piezoelectric layer (see FIG. 35). A structure including an electrode provided inside the hollow region 160, that is, a double-sided IDT structure in which IDT electrodes 11 are provided on both sides of the piezoelectric layer may be adopted (see FIG. 36). An IDT pattern in phase with or opposite to that on the front surface may be provided on the back surface of the piezoelectric layer. The electrode inside the hollow region 160 may include a solid electrode (planar electrode) instead of the IDT electrode 11 (see FIG. 37). The solid electrode may be set to, for example, a ground potential, or may be a floating electrode that is not connected to other electrodes.

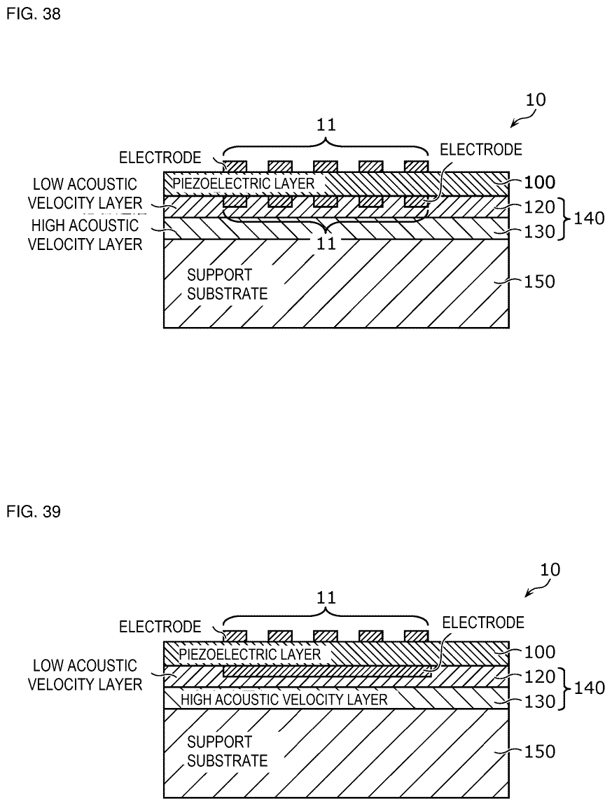

The IDT electrode 11 on the back surface of the piezoelectric layer may be filled with a low acoustic velocity layer material, instead of being provided in the hollow region 160 (see FIG. 38). The electrode on the back surface of the piezoelectric layer may be a solid electrode instead of the IDT electrode 11 (see FIG. 39).

### Example Embodiment 2

In Example Embodiment 2 of the present invention, a ladder acoustic wave filter device including the acoustic wave resonator 10 according to Example Embodiment 1 will be described.

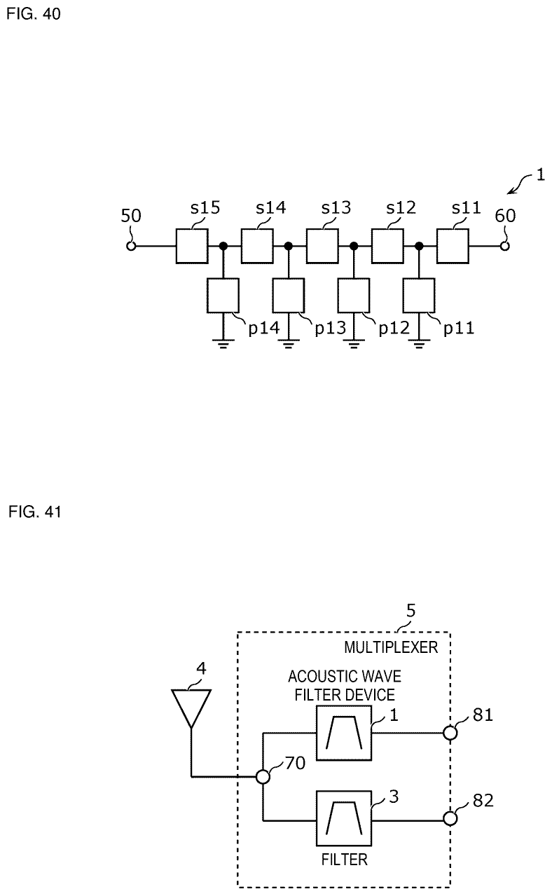

FIG. 40 is a diagram showing a circuit configuration of an acoustic wave filter device 1 according to Example Embodiment 2. As shown in FIG. 40, the acoustic wave filter device 1 includes series arm resonators s11, s12, s13, s14, and s15, parallel arm resonators p11, p12, p13, and p14, and terminals 50 and 60.

The series arm resonators s11 to s15 are connected in series with each other between the terminal 50 and the terminal 60. The parallel arm resonators p11 to p14 are connected in parallel with each other between the connection points of the terminal 50, the series arm resonators s11 to s15, and the terminal 60 and a reference terminal (ground). With this connection configuration of the series arm resonators s11 to s15 and the parallel arm resonators p11 to p14, the acoustic wave filter device 1 defines a ladder band pass filter. Circuit elements such as, for example, inductors may be inserted between the parallel arm resonators p11 to p14 and the ground.

In Example Embodiment 2, the acoustic wave resonator 10 described above may be used for all of the series arm resonators s11 to s15 and the parallel arm resonators p11 to p14 among the resonators included in the acoustic wave filter device 1. Alternatively, the acoustic wave resonator 10 described above may be used for only the parallel arm resonators p11 to p14 among the resonators included in the acoustic wave filter device 1. Alternatively, the acoustic wave resonator 10 described above may be used for the parallel arm resonator p14 or the series arm resonator s15 that is closest to the terminal 50 connected to a common terminal, among the resonators included in the acoustic wave filter device 1.

The acoustic wave filter device 1 may have any configuration including the configuration of the acoustic wave resonator 10 according to Example Embodiment 1 . The circuit configuration shown in FIG. 40 is only an example, and the number of series arm resonators, the number of parallel arm resonators, the connection points of the inductors, and the like are not limited to the configuration shown in FIG. 40. Although a ladder circuit configuration is shown in FIG. 40, a longitudinally coupled resonant circuit may also be included.

### Example Embodiment 3

In Example Embodiment 3 of the present invention, description will be provided of a multiplexer having a configuration in which a plurality of filters including the acoustic wave filter device 1 according to Example Embodiment 2 are directly or indirectly connected to a common terminal.

FIG. 41 is a diagram showing a circuit configuration of a multiplexer 5 according to Example Embodiment 3 and its peripheral circuit (antenna 4). The multiplexer 5 shown in FIG. 41 includes an acoustic wave filter device 1, a filter 3, a common terminal 70, and input/output terminals 81 and 82.

In the acoustic wave filter device 1, the terminal 50 of the acoustic wave filter device 1 is connected to the common terminal 70, and the terminal 60 of the acoustic wave filter device 1 is connected to the input/output terminal 81.

The filter 3 is connected to the common terminal 70 and the input/output terminal 82. The filter 3 is, for example, a ladder acoustic wave filter including parallel arm resonators and series arm resonators, but may be an LC filter or the like, and its circuit configuration is not particularly limited. A pass band of the acoustic wave filter device 1 may be located on the lower frequency side than a pass band of the filter 3.

The acoustic wave filter device 1 and the filter 3 do not have to be directly connected to the common terminal 70 as shown in FIG. 41. The acoustic wave filter device 1 and the filter 3 may be indirectly connected to the common terminal 70 through, for example, an impedance matching circuit, a phase shifter, a circulator, or a switch element capable of selecting two or more filters, for example.

In the present example embodiment, the multiplexer 5 has a circuit configuration in which two filters are connected to the common terminal 70. However, the number of filters connected to the common terminal 70 is not limited to two and may be three or more.

Specifically, the multiplexer according to the present example embodiment may include a plurality of filters including the acoustic wave filter device 1, and the input/output terminal and one of the input/output terminals of each of the plurality of filters may be connected directly or indirectly to the common terminal. At least one of the plurality of filters excluding the acoustic wave filter device 1 may have a pass band higher than the frequency of the pass band of the acoustic wave filter device 1.

An acoustic wave resonators and the like according to example embodiments of the present invention will be described.

An acoustic wave resonator 10 of Example 1 includes a piezoelectric layer 100 and an IDT electrode 11 provided on a main surface 100a of the piezoelectric layer 100. The IDT electrode 11 includes a plurality of electrode fingers 11a and 11b. The plurality of electrode fingers 11a and 11b are arranged in a first direction d1 along the main surface 100a of the piezoelectric layer 100. A region where the IDT electrode 11 is provided on the main surface 100a of the piezoelectric layer 100 includes a plurality of split regions D provided in a matrix in the first direction d1 and a second direction d2 in which the electrode fingers 11a and 11b extend. The split region D is a region including some of the plurality of electrode fingers 11a and 11b and a portion of the electrode fingers in the longitudinal direction. The plurality of split regions D include one split region Ba and the other split region Bb adjacent to each other in the second direction d2. A duty in one split region Ba is larger than a duty in the other split region Bb. An electrode finger pitch in one split region Ba is smaller than an electrode finger pitch in the other split region Bb.

Such a difference in duty between the split regions Ba and Bb adjacent to each other in the second direction d2 makes it possible to disperse the generation frequency of unwanted waves. This makes it possible to prevent an increase in unwanted waves.

An acoustic wave resonator 10 of Example 2 is the acoustic wave resonator according to Example 1, in which the plurality of split regions D include one split region Aa and the other split region Ab adjacent to each other in the first direction d1. A duty in one split region Aa may be larger than a duty in the other split region Ab. An electrode finger pitch in one split region Aa may be smaller than an electrode finger pitch in the other split region Ab.

Such a difference in duty between the split regions Aa and Ab adjacent to each other in the first direction dl makes it possible to disperse the generation frequency of unwanted waves. This makes it possible to prevent an increase in unwanted waves.

An acoustic wave resonator 10 of Example 3 is the acoustic wave resonator according to Example 1 or 2, in which, in one split region Aa and the other split region Ab adjacent to each other in the first direction d1, a resonant frequency determined based on the duty and electrode finger pitch in one split region Aa may match or substantially match a resonant frequency determined based on the duty and electrode finger pitch in the other split region Ab. In one split region Ba and the other split region Bb adjacent to each other in the second direction d2, a resonant frequency determined based on the duty and electrode finger pitch in one split region Ba may match or substantially match a resonant frequency determined based on the duty and electrode finger pitch in the other split region Bb.

Such matching resonant frequencies can reduce or prevent a decrease in impedance ratio and can reduce or prevent characteristic degradation in a main mode.

An acoustic wave resonator 10 of Example 4 is the acoustic wave resonator according to any one of Examples 1 to 3, in which the duty and the electrode finger pitch may be constant in each of the plurality of split regions D.

This allows the resonant frequencies to easily match or substantially match between the split regions D. This makes it possible to reduce or prevent a decrease in impedance ratio and to prevent characteristic degradation in the main mode.

An acoustic wave resonator 10 of Example 5 is the acoustic wave resonator according to any one of Examples 1 to 4, in which the plurality of split regions D may have the same or substantially the same length in the first direction d1, and the plurality of split regions D may have the same or substantially the same length in the second direction d2.

This allows the resonant frequencies to easily match or substantially match between the split regions D. This makes it possible to reduce or prevent a decrease in impedance ratio and to prevent characteristic degradation in the main mode.

An acoustic wave resonator 10 of Example 6 is the acoustic wave resonator according to any one of Examples 1 to 5, in which the plurality of split regions D may be configured such that a predetermined duty moves and changes continuously in the first direction d1 and the second direction d2.

With the duty of the split regions D thus configured so as to move and change continuously, the generation frequency of unwanted waves can be appropriately dispersed, thus making it possible to prevent an increase in unwanted waves.

An acoustic wave resonator 10 of Example 7 is the acoustic wave resonator according to any one of Examples 1 to 5, in which the split regions D may be configured such that the duty of the split regions D changes linearly in at least a portion of a coordinate system with a first axis representing an arrangement number of the electrode fingers 11a and 11b sequentially arranged in the first direction d1 and a second axis representing the duty.

With the duty of the split region D thus configured so as to change linearly, the generation frequency of unwanted waves can be appropriately dispersed, thus making it possible to prevent an increase in unwanted waves.

An acoustic wave resonator 10 of Example 8 is the acoustic wave resonator according to Example 7, in which the split regions D may be configured such that the duty of the split regions D changes linearly and continuously in the above coordinate system.

With such a configuration, the generation frequency of unwanted waves can be appropriately dispersed, thus making it possible to prevent an increase in unwanted waves.

An acoustic wave resonator 10 of Example 9 is the acoustic wave resonator according to Example 7, in which the split regions D may be configured such that the duty of the split regions D generates a triangular waveform in the above coordinate system.

With such a configuration, the generation frequency of unwanted waves can be appropriately dispersed, thus making it possible to prevent an increase in unwanted waves.

An acoustic wave resonator 10 of Example 10 is the acoustic wave resonator according to Example 7, in which the split regions D may be configured such that the duty of the split regions D generates a sawtooth waveform in the above coordinate system.

With such a configuration, the generation frequency of unwanted waves can be appropriately dispersed, thus making it possible to prevent an increase in unwanted waves.

An acoustic wave resonator 10 of Example 11 is the acoustic wave resonator according to Example 7, in which the plurality of split regions D may be configured such that the duties of the plurality of split regions D generate a plurality of waveforms with the same shape but different phases in the above coordinate system.

With the duty of the split regions D thus configured so as to generate a plurality of waveforms, the generation frequency of unwanted waves can be appropriately dispersed, thus making it possible to prevent an increase in unwanted waves.

An acoustic wave resonator 10 of Example 12 is the acoustic wave resonator according to any one of Examples 1 to 5, in which the split regions D may be configured such that the duty of the split regions D changes in a curved manner in at least a portion of a coordinate system with a first axis representing an arrangement number of the electrode fingers 11a and 11b sequentially arranged in the first direction d1 and a second axis representing the duty.

With the duty of the split region D thus configured so as to change in a curved manner, the generation frequency of unwanted waves can be appropriately dispersed, thus making it possible to prevent an increase in unwanted waves.

An acoustic wave resonator 10 of Example 13 is the acoustic wave resonator according to Example 12, in which the split regions D may be configured such that the duty of the split regions D generates a curved waveform with less than one period or more than one period in the above coordinate system.

With such a configuration, the generation frequency of unwanted waves can be appropriately dispersed, thus making it possible to prevent an increase in unwanted waves.

An acoustic wave resonator 10 of Example 14 is the acoustic wave resonator according to Example 12, in which the plurality of split regions D may be configured such that the duties of the plurality of split regions D generate a plurality of waveforms with the same or substantially the same shape but different phases in the above coordinate system.

With the duty of the split regions D thus configured so as to generate a plurality of waveforms, the generation frequency of unwanted waves can be appropriately dispersed, thus making it possible to prevent an increase in unwanted waves.

An acoustic wave resonator 10 of Example 15 is the acoustic wave resonator according to any one of Examples 1 to 14, in which the IDT electrode 11 includes piston mode formation regions 35 located at both end portions 36 of the electrode fingers 11a and 11b. The piston mode formation regions 35 may be included in split regions D located at both ends in the second direction d2, among the plurality of split regions D.

This configuration allows a piston operation to be applied to the IDT, making it possible to reduce or prevent characteristic degradation in the main mode.

An acoustic wave resonator 10 of Example 16 is the acoustic wave resonator according to any one of Examples 1 to 15, in which the IDT electrode 11 further includes a pair of comb-shaped electrodes 11A and 11B, the pair of comb-shaped electrodes 11A and 11B each include a plurality of electrode fingers 11a and 11b and a first busbar electrode 31 connecting one ends of the plurality of electrode fingers 11a and 11b, and a high acoustic velocity portion 39 may be provided between both end portions 36 of the electrode fingers 11a and 11b and the first busbar electrode 31.

An acoustic wave resonator 10 of Example 17 is the acoustic wave resonator according to any one of Examples 1 to 16, in which the IDT electrode 11 further includes a pair of comb-shaped electrodes 11A and 11B. The pair of comb-shaped electrodes 11A and 11B each include a plurality of electrode fingers 11a and 11b, a first busbar electrode 31 connecting one ends of the plurality of electrode fingers 11a and 11b, and a second busbar electrode 32 thinner than the first busbar electrode 31. The second busbar electrode 32 may be provided parallel to the first busbar electrode 31 between the first busbar electrode 31 and the plurality of split regions D.

This configuration can reduce or prevent characteristic degradation in the main mode.

An acoustic wave resonator 10 of Example 18 is the acoustic wave resonator according to any one of Examples 1 to 17, in which the piezoelectric layer 100 may be provided on a support substrate 150.

An acoustic wave resonator 10 of Example 19 is the acoustic wave resonator according to Example 18, in which a hollow region 160 may be provided between the piezoelectric layer 100 and the support substrate 150.

An acoustic wave resonator 10 of Example 20 is the acoustic wave resonator according to Example 18, in which an intermediate layer 140 may be provided between the piezoelectric layer 100 and the support substrate 150.

An acoustic wave resonator 10 of Example 21 is the acoustic wave resonator according to any one of Examples 1 to 16, which may further include a high acoustic velocity layer 130 in which an acoustic velocity of propagating bulk waves is greater than an acoustic velocity of acoustic waves propagating through the piezoelectric layer 100, and a low acoustic velocity layer 120 disposed between the high acoustic velocity layer 130 and the piezoelectric layer 100, in which an acoustic velocity of propagating bulk waves is less than the acoustic velocity of the acoustic waves propagating through the piezoelectric layer 100.

This multilayer structure makes it possible to significantly increase the Q factor of the acoustic wave resonator 10 at the resonant frequency and the anti-resonant frequency. Since the acoustic wave resonator 10 with a high Q factor can be configured, a filter with low insertion loss can be configured using the acoustic wave resonator 10.

An acoustic wave resonator 10 of Example 22 is the acoustic wave resonator according to any one of Examples 1 to 17, in which the piezoelectric layer 100 may be a piezoelectric substrate.

An acoustic wave filter device 1 of Example 23 includes the acoustic wave resonator 10 according to any one of Examples 1 to 21.

This makes it possible to provide the acoustic wave filter device 1 including the acoustic wave resonator 10 capable of suppressing unwanted waves.

### Other Example Embodiments and the Like

Although the acoustic wave resonators and the acoustic wave filter devices according to example embodiments of the present invention have been described above with reference to the example embodiments and examples thereof, the acoustic wave resonators and the acoustic wave filter devices of the present invention are not limited to the above example embodiments and examples thereof. The present invention also includes other example embodiments obtained by combining any of the components in the above example embodiments and examples, examples obtained by applying various modifications to the above example embodiments that can be conceived by those skilled in the art without departing from the scope and spirit of the present invention, and various devices including the acoustic wave resonators and the acoustic wave filter devices of the example embodiments and example.

For example, a piezoelectric substrate or the like including a piezoelectric layer may be configured to have the following configuration.

The piezoelectric substrate may be made of, for example, a piezoelectric material such as aluminum nitride, lithium tantalate, lithium niobate, or quartz crystal, a ceramic such as alumina, sapphire, magnesia, silicon nitride, silicon carbide, zirconia, cordierite, mullite, steatite, or forsterite, a dielectric material such as diamond or glass, a semiconductor such as silicon or gallium nitride, or resin, or a material made mainly of the above materials.

The piezoelectric substrate may be a substrate including a piezoelectric layer at least in a portion thereof, or may have a multilayer structure including a piezoelectric layer. The piezoelectric substrate may include, for example, a high acoustic velocity support substrate, a low acoustic velocity film, and a piezoelectric layer, and may have a structure in which the high acoustic velocity support substrate, the low acoustic velocity film, and the piezoelectric layer are laminated in this order.

The configurations of the high acoustic velocity support substrate, the low acoustic velocity film, and the piezoelectric layer will be described below.

The piezoelectric layer is made of, for example, θ° Y-cut X-propagation LiTaO₃ piezoelectric single crystal or piezoelectric ceramics (lithium tantalate single crystal or ceramics cut on a plane with a normal line set on an axis rotated about an X axis by θ° in a Z-axis direction from a Y axis, which is single crystal or ceramics through which surface acoustic waves propagate in the X-axis direction).

The high acoustic velocity support substrate is a substrate that supports the low acoustic velocity film, the piezoelectric layer, and the electrode 110. The high acoustic velocity support substrate is a substrate in which the acoustic velocity of bulk waves in the high acoustic velocity support substrate is greater than that of the surface acoustic waves and boundary acoustic waves propagating through the piezoelectric layer. The high acoustic velocity support substrate defines and functions to confine the surface acoustic waves to the portion where the piezoelectric layer and the low acoustic velocity film are laminated, and to prevent leakage below the high acoustic velocity support substrate.

The high acoustic velocity support substrate is a silicon substrate, for example. The high acoustic velocity support substrate may be made of, for example, a piezoelectric material such as aluminum nitride, lithium tantalate, lithium niobate, or quartz crystal, a ceramic such as alumina, sapphire, magnesia, silicon nitride, silicon carbide, zirconia, cordierite, mullite, steatite, forsterite, spinel, or sialon, a dielectric material such as aluminum oxide, silicon oxynitride, diamond-like carbon (DLC), or diamond, or a semiconductor such as silicon, or a material made mainly of the above materials. The spinel includes, for example, an aluminum compound including one or more of Mg, Fe, Zn, Mn, or the like, or oxygen. Examples of the spinel include MgAl₂O₄, FeAl₂O₄, ZnAl₂O₄, or MnAl₂O₄.

The low acoustic velocity film is a film in which the acoustic velocity of bulk waves in the low acoustic velocity film is less than the acoustic velocity of the acoustic waves propagating through the piezoelectric layer, and is disposed between the piezoelectric layer and the high acoustic velocity support substrate. This structure and the essential property of the acoustic wave having its energy concentrated in a medium with low acoustic velocity reduce or prevent the leakage of surface acoustic wave energy to outside of the IDT electrode.

The low acoustic velocity film is a film made mainly of silicon dioxide (SiO₂), for example. The material of the low acoustic velocity film is not limited to the above. For example, a dielectric material such as glass, silicon oxide, silicon oxynitride, lithium oxide, tantalum oxide, or a compound of silicon oxide with fluorine, carbon, or boron added, or a material made mainly of the above materials can also be used.

The multilayer structure of the piezoelectric substrate described above makes it possible to significantly increase the Q factor of the acoustic wave resonator at the resonant frequency and anti-resonant frequency, compared to a structure using a single layer of piezoelectric substrate. In other words, a surface acoustic wave resonator with a high Q factor can be configured, thus making it possible to use this surface acoustic wave resonator to form a filter with low insertion loss.

The high acoustic velocity support substrate may have a structure in which a support substrate and a high acoustic velocity film, in which the acoustic velocity of propagating bulk waves is greater than that of acoustic waves such as surface acoustic waves or boundary waves propagating through the piezoelectric layer, are laminated.

In the case of this multilayer structure, the support substrate can be made of, for example, a piezoelectric material such as sapphire, lithium tantalate, lithium niobate, or quartz crystal, various ceramics such as alumina, magnesia, silicon nitride, aluminum nitride, silicon carbide, zirconia, cordierite, mullite, steatite, or forsterite, a dielectric material such as glass, or a semiconductor such as silicon or gallium nitride, a resin substrate, and other materials.

The high acoustic velocity film may be made of, for example, a piezoelectric material such as aluminum nitride, lithium tantalate, lithium niobate, or quartz crystal, a ceramic such as alumina, sapphire, magnesia, silicon nitride, silicon carbide, zirconia, cordierite, mullite, steatite, forsterite, spinel, or sialon, a dielectric material such as aluminum oxide, silicon oxynitride, diamond-like carbon (DLC), or diamond, or a semiconductor such as silicon, or a material made mainly of the above materials. The spinel includes, for example, an aluminum compound including Mg, Fe, Zn, Mn, or the like, and oxygen. Examples of the spinel include MgAl₂O₄, FeAl₂O₄, ZnAl₂O₄, or MnAl₂O₄.

The materials of the layers used in the multilayer structure of the piezoelectric substrate are merely an example, and may be changed depending on the characteristics that should be provided among the required high-frequency propagation characteristics, for example.

Example embodiments of the present invention can be widely used as an acoustic wave resonator and an acoustic wave filter device that can reduce or prevent unwanted waves in communication devices such as a mobile phone, for example.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave resonator comprising:
a piezoelectric layer; and
an IDT electrode on a main surface of the piezoelectric layer; wherein
the IDT electrode includes a plurality of electrode fingers;
the plurality of electrode fingers are arranged in a first direction along the main surface of the piezoelectric layer;
a region on the main surface of the piezoelectric layer where the IDT electrode is provided includes a plurality of split regions in a matrix in the first direction and a second direction in which the electrode fingers extend;
a split region among the plurality of split regions includes some of the plurality of electrode fingers and a portion of the electrode fingers in a longitudinal direction;
the plurality of split regions include one split region and another split region adjacent to each other in the second direction; and
a duty in the one split region in the second direction is larger than a duty in the another split region in the second direction, and an electrode finger pitch in the one split region in the second direction is smaller than an electrode finger pitch in the another split region in the second direction.

2. The acoustic wave resonator according to claim 1, wherein
the plurality of split regions include one split region and another split region adjacent to each other in the first direction; and
a duty in the one split region in the first direction is larger than a duty in the other split region in the first direction, and an electrode finger pitch in the one split region in the first direction is smaller than an electrode finger pitch in the other split region in the first direction.

3. The acoustic wave resonator according to claim 2, wherein
in the one split region and the other split region adjacent to each other in the first direction, a resonant frequency determined based on the duty and the electrode finger pitch in the one split region matches or substantially matches a resonant frequency determined based on the duty and the electrode finger pitch in the other split region; and
in the one split region and the other split region adjacent to each other in the second direction, a resonant frequency determined based on the duty and the electrode finger pitch in the one split region matches or substantially matches a resonant frequency determined based on the duty and the electrode finger pitch in the other split region.

4. The acoustic wave resonator according to claim 1, wherein, in each of the plurality of split regions, the duty is constant and the electrode finger pitch is constant.

5. The acoustic wave resonator according to claim 1, wherein
the plurality of split regions have a same or substantially a same length in the first direction; and
the plurality of split regions have a same or substantially a same length in the second direction.

6. The acoustic wave resonator according to claim 1, wherein the plurality of split regions are structured such that the duty moves and changes continuously in the first direction and the second direction.

7. The acoustic wave resonator according to claim 1, wherein the plurality of split regions are structured such that the duty of the plurality of split regions changes linearly in at least a portion of a coordinate system with a first axis representing an arrangement number of the plurality of electrode fingers sequentially arranged in the first direction and a second axis representing the duty.

8. The acoustic wave resonator according to claim 7, wherein the plurality of split regions are structured such that the duty of the plurality of split regions changes linearly and continuously in the coordinate system.

9. The acoustic wave resonator according to claim 7, wherein the plurality of split regions are structured such that the duty of the plurality of split regions generates a triangular waveform in the coordinate system.

10. The acoustic wave resonator according to claim 7, wherein the plurality of split regions are structured such that the duty of the plurality of split regions generates a sawtooth waveform in the coordinate system.

11. The acoustic wave resonator according to claim 7, wherein the plurality of split regions are structured such that the duties of the plurality of split regions generate a plurality of waveforms having a same or substantially a same shape but different phases in the coordinate system.

12. The acoustic wave resonator according to claim 2, wherein the plurality of split regions are structured such that the duty of the plurality of split regions changes in a curved manner in at least a portion of a coordinate system with a first axis representing an arrangement number of the plurality of electrode fingers sequentially arranged in the first direction and a second axis representing the duty.

13. The acoustic wave resonator according to claim 12, wherein the plurality of split regions are structured such that the duty of the plurality of split regions generates a curved waveform with less than one period or more than one period in the coordinate system.

14. The acoustic wave resonator according to claim 12, wherein the plurality of split regions are structured such that the duties of the plurality of split regions generate a plurality of waveforms with a same or substantially a same shape but different phases in the coordinate system.

15. The acoustic wave resonator according to claim 1, wherein
the IDT electrode includes piston mode formation regions located at both end portions of the electrode fingers; and
the piston mode formation regions are included in split regions located at both ends in the second direction, among the plurality of split regions.

16. The acoustic wave resonator according to claim 1, wherein
the IDT electrode includes a pair of comb-shaped electrodes;
the pair of comb-shaped electrodes each include the plurality of electrode fingers and a first busbar electrode connecting ends of the plurality of electrode fingers; and
a high acoustic velocity portion is provided between both end portions of the electrode fingers and the first busbar electrode.

17. The acoustic wave resonator according to claim 1, wherein
the IDT electrode includes a pair of comb-shaped electrodes;
the pair of comb-shaped electrodes each include the plurality of electrode fingers, a first busbar electrode connecting one ends of the plurality of electrode fingers, and a second busbar electrode thinner than the first busbar electrode; and
the second busbar electrode is parallel or substantially parallel to the first busbar electrode between the first busbar electrode and the plurality of split regions.

18. The acoustic wave resonator according to claim 1, wherein the piezoelectric layer includes a support substrate.

19. The acoustic wave resonator according to claim 18, wherein a hollow region is provided between the piezoelectric layer and the support substrate.

20. The acoustic wave resonator according to claim 18, wherein an intermediate layer is provided between the piezoelectric layer and the support substrate.

21. The acoustic wave resonator according to claim 1, further comprising:
a high acoustic velocity layer in which an acoustic velocity of propagating bulk waves is greater than an acoustic velocity of acoustic waves propagating through the piezoelectric layer; and
a low acoustic velocity layer between the high acoustic velocity layer and the piezoelectric layer, in which an acoustic velocity of propagating bulk waves is less than the acoustic velocity of the acoustic waves propagating through the piezoelectric layer.

22. The acoustic wave resonator according to claim 1, wherein the piezoelectric layer includes a piezoelectric substrate.

23. An acoustic wave filter device comprising:
the acoustic wave resonator according to claim 1.
